(19) United States
(12) Patent Application Publication
(10) Pub. No.: US 2026/0230086 A1
(43) Pub. Date: Aug. 6, 2026

(54) DIGITAL-TO-ANALOG CONVERTER (DAC) CIRCUIT USING TAIL CURRENT SOURCE SHARED SUB-DACS

(71) Applicant: MEDIATEK INC., Hsinchu City (TW)

(72) Inventors: Hung-Yi Huang, Hsinchu City (TW); Chung-Wei Hsu, Hsinchu City (TW); Kid Nuo Lim, Hsinchu City (TW); Yu-Sian Lin, Hsinchu City (TW); Min-Jui Chiu, Hsinchu City (TW); Wei-Te Lin, Hsinchu City (TW)

(73) Assignee: MEDIATEK INC., Hsinchu City (TW)

(21) Appl. No.: 19/464,572

(22) Filed: Jan. 29, 2026

Related U.S. Application Data
(60) Provisional application No. 63/753,414, filed on Feb. 3, 2025.

(51) Int. Cl. H03M 1/66

(52) U.S. Cl. CPC H03M 1/662

(57) ABSTRACT

A digital-to-analog converter (DAC) circuit includes a shared current source, a first signal path circuit, a second signal path circuit, and a return-to-zero (RZ) path circuit. The first signal path circuit includes a first data switch circuit and a first clock switch circuit that are series-connected between the shared current source and a data output port. The second signal path circuit includes a second data switch circuit and a second clock switch circuit that are series-connected between the shared current source and the data output port. The RZ path circuit is coupled between the shared current source and the data output port.

### CROSS REFERENCE TO RELATED APPLICATIONS

This application claims the benefit of U.S. Provisional Application No. 63/753,414, filed on Feb. 3, 2025. The content of the application is incorporated herein by reference.

### BACKGROUND

The present invention relates to converting a digital input into an analog output, and more particularly, to a digital-to-analog converter (DAC) circuit using tail current source shared (CS-shared) sub-DACs.

A time-interleaved DAC (TI-DAC) boosts high-speed digital-to-analog conversion by splitting a fast data stream into multiple slower data streams, processed in parallel by several identical DAC cells (also called sub-DACs) operating at staggered times, then recombining their outputs to achieve a much higher overall data rate than a single DAC could manage. Taking an 8-bit (8b) 200 GSPs (Giga Samples Per Second) TI-DAC for example, it may use eight 8b 25GSPs sub-DACs each for outputting an analog output of one 8b symbol (which consists of 8 bits from most significant bit (MSB) to least significant bit (LSB)) in one unit interval (UI). The conventional TI-DAC is power and area hungry due to each sub-DAC having its current source array. Specifically, static power and area are proportional to the number of sub-DACs. Consequently, digital-to-analog conversion using multi-way interleaving is area and power consuming, resulting in poor performance, power, and area (PPA) performance. In addition, the conventional sub-DAC requires a narrow pulse width of a return-to-zero (RZ) signal for providing an analog output to a data output port. Taking the conventional 200 GSPs TI-DAC using eight 25GSPs sub-DACs for example, a 5 ps pulse width (i.e., 1 UI=5 ps) is needed to trigger each of the 25GSPs sub-DACs to output its analog output. However, 1 UI is insufficient for internal node settling, causing an inter-symbol interference (ISI) issue. Furthermore, it is difficult to generate a 5 ps pulse width (i.e., 1 UI), and narrow pulse width generation may generate a 5 ps pulse with an incomplete pulse shape. Thus, there is a need for innovative high-frequency digital-to-analog conversion achieved by multi-way interleaving that is free of some or all of these issues.

### SUMMARY

One of the objectives of the claimed invention is to provide a DAC circuit using tail CS-shared sub-DACs.

According to one aspect of the present invention, an exemplary DAC circuit is disclosed. The exemplary DAC circuit includes a first sub-DAC. The first sub-DAC includes a shared current source, a first signal path circuit, a second signal path circuit, and a return-to-zero (RZ) path circuit. The first signal path circuit includes a first data switch circuit and a first clock switch circuit. The first data switch circuit is controlled by a first set of control signals, wherein the first set of control signals depends on a first input data. The first clock switch circuit is controlled by a first control signal, wherein the first control signal is independent of the first input data, and the first data switch circuit and the first clock switch circuit are series-connected between the shared current source and a data output port. The second signal path circuit includes a second data switch circuit and a second clock switch circuit. The second data switch circuit is controlled by a second set of control signals, wherein the second set of control signals depends on a second input data. The second clock switch circuit is controlled by a second control signal, wherein the second control signal is independent of the second input data, and the second data switch circuit and the second clock switch circuit are series-connected between the shared current source and the data output port. The RZ path circuit is controlled by at least one RZ control signal, wherein the at least one RZ control signal is independent of the first input data and the second input data, and the RZ path circuit is coupled between the shared current source and a dummy output node.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a signal processing system according to an embodiment of the present invention.

FIG. 2 is a diagram illustrating another signal processing system according to an embodiment of the present invention.

FIG. 3 is a diagram illustrating a first TI-DAC using multiple tail CS-shared sub-DACs according to an embodiment of the present invention.

FIG. 4 is a diagram illustrating waveforms of clocks and control signals used by the tail CS-shared sub-DAC according to an embodiment of the present invention.

FIG. 5 is a diagram illustrating a second TI-DAC using multiple tail CS-shared sub-DACs according to an embodiment of the present invention.

FIG. 6 is a diagram illustrating settings of clocks used by the tail CS-shared sub-DAC that is enabled under ENB_AB=ENB_CD=ENB_EF=ENB_GH=0 according to an embodiment of the present invention.

FIG. 7 is a diagram illustrating settings of clocks used by the tail CS-shared sub-DAC that is enabled under ENB_AB=ENB_EF=0 & ENB_CD=ENB_GH=1 according to an embodiment of the present invention.

FIG. 8 is a diagram illustrating settings of clocks used by the tail CS-shared sub-DAC that is enabled under ENB_AB=0 & ENB_CD=ENB_EF=ENB_GH=1 according to an embodiment of the present invention.

FIG. 9 is a diagram illustrating a third TI-DAC using multiple tail CS-shared sub-DACs according to an embodiment of the present invention.

FIG. 10 is a diagram illustrating waveforms of input data, clocks and control signals used by the tail CS-shared sub-DAC according to an embodiment of the present invention.

FIG. 11 is a diagram illustrating an RZ phase (Reset phase of A) of the tail CS-shared sub-DAC according to an embodiment of the present invention.

FIG. 12 is a diagram illustrating a period in which the tail CS-shared sub-DAC operates in the RZ phase (Reset phase of A).

FIG. 13 is a diagram illustrating a signal phase of A of the tail CS-shared sub-DAC according to an embodiment of the present invention.

FIG. 14 is a diagram illustrating a period in which the tail CS-shared sub-DAC operates in the signal phase of A.

FIG. 15 is a diagram illustrating an RZ phase (Reset phase of B) of the tail CS-shared sub-DAC according to an embodiment of the present invention.

FIG. 16 is a diagram illustrating a period in which the tail CS-shared sub-DAC operates in the RZ phase (Reset phase of B).

FIG. 17 is a diagram illustrating a signal phase of B of the tail CS-shared sub-DAC according to an embodiment of the present invention.

FIG. 18 is a diagram illustrating a period in which the tail CS-shared sub-DAC operates in the signal phase of B.

FIG. 19 is a diagram illustrating a fourth TI-DAC using multiple tail CS-shared sub-DACs according to an embodiment of the present invention.

FIG. 20 is a diagram illustrating settings of clocks used by the tail CS-shared sub-DAC that is enabled under ENB_AB=ENB_CD=ENB_EF=ENB_GH=0 according to an embodiment of the present invention.

FIG. 21 is a diagram illustrating settings of clocks used by the tail CS-shared sub-DAC that is enabled under ENB_AB=ENB_EF=0 & ENB_CD=ENB_GH=1 according to an embodiment of the present invention.

FIG. 22 is a diagram illustrating settings of clocks used by the tail CS-shared sub-DAC that is enabled under ENB_AB=0 & ENB_CD=ENB_EF=ENB_GH=1 according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

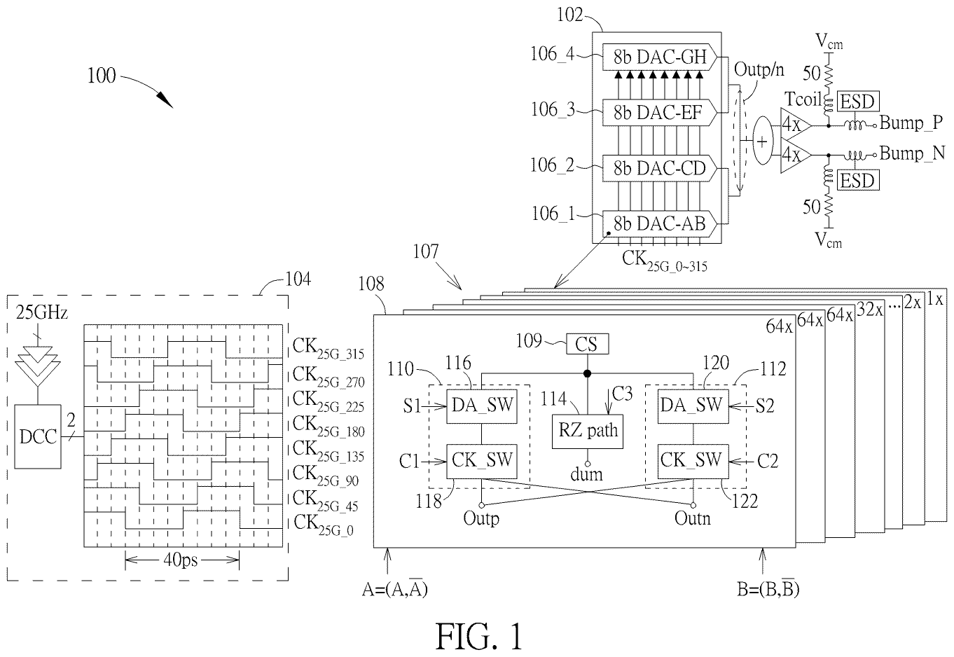

FIG. 1 is a diagram illustrating a signal processing system according to an embodiment of the present invention. The signal processing system 100 includes a DAC circuit 102 and a clock generator circuit 104. In this embodiment, the DAC circuit 102 is a TI-DAC using the proposed tail CS-shared sub-DACs 106_1, 106_2, 106_3, 106_4. For example, the DAC circuit 102 is an 8b 200 GSPs eight-channel TI-DAC having eight 8b 25GSPs sub-DACs for dealing with digital-to-analog conversion of input data A, B, C, D, E, F, G, H, where each of the tail CS-shared sub-DACs 106_1, 106_2, 106_3, 106_4 includes two sub-DACs (i.e., two channels) that share the same current source. As shown in FIG. 1, the tail CS-shared sub-DAC (labeled by “8b DAC-AB”) 106_1 includes sub-DACs (which can be used for dealing with digital-to-analog conversion of input data A and B) that share the same current source, the tail CS-shared sub-DAC (labeled by “8b DAC-CD”) 106_2 includes sub-DACs (which can be used for dealing with digital-to-analog conversion of input data C and D) that share the same current source, the tail CS-shared sub-DAC (labeled by “8b DAC-EF”) 106_3 includes sub-DACs (which can be used for dealing with digital-to-analog conversion of input data E and F) that share the same current source, and the tail CS-shared sub-DAC (labeled by “8b DAC-GH”) 106_4 includes sub-DACs (which can be used for dealing with digital-to-analog conversion of input data G and H) that share the same current source. Each of the tail CS-shared sub-DACs 106_1, 106_2, 106_3, 106_4 operates according clocks selected from 8-phase clocks CK_{25G_0}, CK_{25G_45}, CK_{25G_90}, CK_{25G_135}, CK_{25G_180}, CK_{25G_225}, CK_{25G_270}, CK_{25G_315} generated from the clock generator circuit 104, where the clocks CK_{25G_0}, CK_{25G_45}, CK_{25G_90}, CK_{25G_135}, CK_{25G_180}, CK_{25G_225}, CK_{25G_270}, CK_{25G_315} have the same frequency (e.g., 25 GHz) but different phases (e.g., 0°, 45°, 90°, 135°, 180°, 225°, 270°, and 315°).

The tail CS-shared sub-DAC 106_1 sequentially receives 8b symbols of the input data A and output an analog output of each 8b symbol (which consists of 8 bits from MSB to LSB) in one UI (1 UI=5 ps), and sequentially receives 8b symbols of the input data B and output an analog output of each 8b symbol (which consists of 8 bits from MSB to LSB) in one UI (1 UI=5 ps). The tail CS-shared sub-DAC 106_2 sequentially receives 8b symbols of the input data C and output an analog output of each 8b symbol (which consists of 8 bits from MSB to LSB) in one UI (1 UI=5 ps), and sequentially receives 8b symbols of the input data D and output an analog output of each 8b symbol (which consists of 8 bits from MSB to LSB) in one UI (1 UI=5 ps). The tail CS-shared sub-DAC 106_3 sequentially receives 8b symbols of the input data E and output an analog output of each 8b symbol (which consists of 8 bits from MSB to LSB) in one UI (1 UI=5 ps), and sequentially receives 8b symbols of the input data F and output an analog output of each 8b symbol (which consists of 8 bits from MSB to LSB) in one UI (1 UI=5 ps). The tail CS-shared sub-DAC 106_4 sequentially receives 8b symbols of the input data G and output an analog output of each 8b symbol (which consists of 8 bits from MSB to LSB) in one UI (1 UI=5 ps), and sequentially receives 8b symbols of the input data H and output an analog output of each 8b symbol (which consists of 8 bits from MSB to LSB) in one UI (1 UI=5 ps). In this embodiment, each of the tail CS-shared sub-DACs 106_1, 106_2, 106_3, 106_4 may employ a segmented DAC architecture for dealing with digital-to-analog conversion of each 8b symbol. For example, each of the tail CS-shared sub-DACs 106_1, 106_2, 106_3, 106_4 may be implemented using a tail CS-shared sub-DAC 107 shown in FIG. 1.

The tail CS-shared sub-DAC 107 may have multiple DAC cells (e.g., current cells) 108, including unary-weighted DAC cells having the same current ratio of 64X and binary-weighted DAC cells having different current ratios of 1X, 2X, 4X, 8X, 16X, 32X. Each of the tail CS-shared sub-DACs 106_1, 106_2, 106_3, 106_4 may have the same sub-DAC design, and each of the DAC cells included in the same tail CS-shared sub-DAC may have the same DAC cell design. For brevity and simplicity, the following uses one tail CS-shared sub-DAC cell as an example of the proposed tail CS-shared sub-DAC. In other words, a tail CS-shared sub-DAC cell is a basic unit of a tail CS-shared sub-DAC. Hence, any sub-DAC using the proposed tail CS-shared sub-DAC cell falls within the scope of the present invention.

As shown in FIG. 1, the tail CS-shared sub-DAC 107 includes a shared current source (labeled by “CS”) 109, a plurality of signal path circuits 110, 112, and a return-to-zero (RZ) path circuit (labeled by “RZ path”) 114. The signal path circuit 110 includes a data switch circuit (labeled by “DA SW”) 116 and a clock switch circuit (labeled by “CK_SW”) 118. The data switch circuit 116 is controlled by a set of control signals 51, where the set of control signals 51 depends on an input data A=(A,Ā). The clock switch circuit 118 is controlled by a control signal C1, wherein the control signal C1 is independent of the input data A=(A,Ā). The data switch circuit 116 and the clock switch circuit 118 are series-connected between the shared current source 109 and a data output port (Outp, Outn). In this embodiment, the data switch circuit 116 is coupled between the shared current source 109 and the clock switch circuit 118, and the clock switch circuit 118 is coupled between the data switch circuit 116 and the data output port (Outp, Outn). In other words, the data switch circuit 116 is close to the shared current source 109, while the clock switch circuit 118 is close to the data output port (Outp, Outn).

The signal path circuit 112 includes a data switch circuit (labeled by “DA SW”) 120 and a clock switch circuit (labeled by “CK_SW”) 122. The data switch circuit 120 is controlled by a set of control signals S2, where the set of control signals S2 depends on an input data (B,B̅). The clock switch circuit 122 is controlled by a control signal C2, wherein the control signal C2 is independent of the input data (B,B̅). The data switch circuit 120 and the clock switch circuit 122 are series-connected between the shared current source 109 and the data output port (Outp, Outn). In this embodiment, the data switch circuit 120 is coupled between the shared current source 109 and the clock switch circuit 122, and the clock switch circuit 122 is coupled between the data switch circuit 120 and the data output port (Outp, Outn). In other words, the data switch circuit 120 is close to the shared current source 109, while the clock switch circuit 122 is close to the data output port (Outp, Outn).

The RZ path circuit 114 is controlled by at least one RZ control signal C3, wherein the at least one RZ control signal C3 is independent of the input data A=(A,Ā) and the input data B=(B,B̅). In addition, the RZ path circuit 114 is coupled between the shared current source 109 and a dummy output node dum.

Regarding the embodiment shown in FIG. 1, the data switch circuit 116/120 is close to the shared current source 109, and the clock switch circuit 118/122 is close to the data output port (Outp, Outn). However, this is for illustrative purposes only, and is not meant to be a limitation of the present invention. Alternatively, a data switch circuit and a clock switch circuit may be swapped.

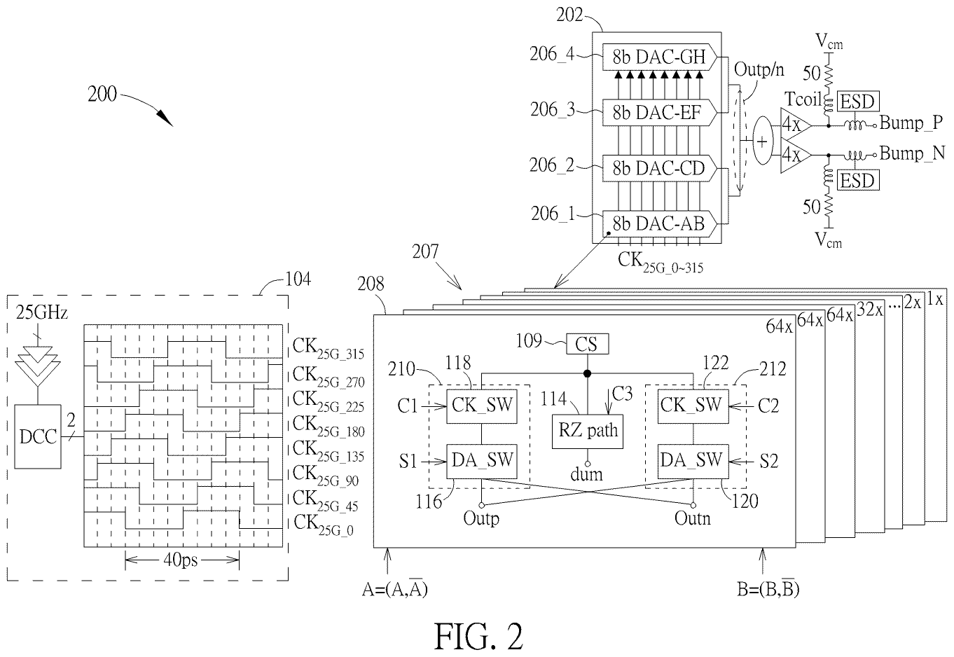

FIG. 2 is a diagram illustrating another signal processing system according to an embodiment of the present invention. The signal processing system 200 includes a DAC circuit 202 and the aforementioned clock generator circuit 104. In this embodiment, the DAC circuit 202 is a TI-DAC using the proposed tail CS-shared sub-DACs 206_1, 206_2, 206_3, 206_4. For example, the DAC circuit 202 is an 8b 200 GSPs eight-channel TI-DAC having eight 8b 25GSPs sub-DACs for dealing with digital-to-analog conversion of input data A, B, C, D, E, F, G, H, where each of the tail CS-shared sub-DACs 206_1, 206_2, 206_3, 206_4 includes two sub-DACs (i.e., two channels) that share the same current source. As shown in FIG. 2, the tail CS-shared sub-DAC (labeled by “8b DAC-AB”) 206_1 includes sub-DACs (which can be used for dealing with digital-to-analog conversion of input data A and B) that share the same current source, the tail CS-shared sub-DAC (labeled by “8b DAC-CD”) 206_2 includes sub-DACs (which can be used for dealing with digital-to-analog conversion of input data C and D) that share the same current source, the tail CS-shared sub-DAC (labeled by “8b DAC-EF”) 206_3 includes sub-DACs (which can be used for dealing with digital-to-analog conversion of input data E and F) that share the same current source, and the tail CS-shared sub-DAC (labeled by “8b DAC-GH”) 206_4 includes sub-DACs (which can be used for dealing with digital-to-analog conversion of input data G and H) that share the same current source. Each of the tail CS-shared sub-DACs 206_1, 206_2, 206_3, 206_4 operates according clocks selected from 8-phase clocks CK_{25G_0}, CK_{25G_45}, CK_{25G_90}, CK_{25G_135}, CK_{25G_180}, CK_{25G_225}, CK_{25G_270}, CK_{25G_315} generated from the clock generator circuit 104, where the clocks CK_{25G_0}, CK_{25G_45}, CK_{25G_90}, CK_{25G_135}, CK_{25G_180}, CK_{25G_225}, CK_{25G_270}, CK_{25G_315} have the same frequency (e.g., 25 GHz) but different phases (e.g., 0°, 45°, 90°, 135°, 180°, 225°, 270°, and 315°).

The tail CS-shared sub-DAC 206_1 sequentially receives 8b symbols of the input data A and output an analog output of each 8b symbol (which consists of 8 bits from MSB to LSB) in one UI (1 UI=5 ps), and sequentially receives 8b symbols of the input data B and output an analog output of each 8b symbol (which consists of 8 bits from MSB to LSB) in one UI (1 UI=5 ps). The tail CS-shared sub-DAC 206_2 sequentially receives 8b symbols of the input data C and output an analog output of each 8b symbol (which consists of 8 bits from MSB to LSB) in one UI (1 UI=5 ps), and sequentially receives 8b symbols of the input data D and output an analog output of each 8b symbol (which consists of 8 bits from MSB to LSB) in one UI (1 UI=5 ps). The tail CS-shared sub-DAC 206_3 sequentially receives 8b symbols of the input data E and output an analog output of each 8b symbol (which consists of 8 bits from MSB to LSB) in one UI (1 UI=5 ps), and sequentially receives 8b symbols of the input data F and output an analog output of each 8b symbol (which consists of 8 bits from MSB to LSB) in one UI (1 UI=5 ps). The tail CS-shared sub-DAC 206_4 sequentially receives 8b symbols of the input data G and output an analog output of each 8b symbol (which consists of 8 bits from MSB to LSB) in one UI (1 UI=5 ps), and sequentially receives 8b symbols of the input data H and output an analog output of each 8b symbol (which consists of 8 bits from MSB to LSB) in one UI (1 UI=5 ps). In this embodiment, each of the tail CS-shared sub-DACs 206_1, 206_2, 206_3, 206_4 may employ a segmented DAC architecture for dealing with digital-to-analog conversion of each 8b symbol. For example, each of the tail CS-shared sub-DACs 206_1, 206_2, 206_3, 206_4 may be implemented using a tail CS-shared sub-DAC 207 shown in FIG. 2.

The tail CS-shared sub-DAC 207 has a plurality of DAC cells (e.g., current cells) 208, including unary-weighted DAC cells each having a current ratio of 64X, and binary-weighted DAC cells having current ratios of 1X, 2X, 4X, 8X, 16X, 32X. Each of the tail CS-shared sub-DACs 206_1, 206_2, 206_3, 206_4 may have the same sub-DAC design, and each of the DAC cells included in the same tail CS-shared sub-DAC may have the same DAC cell design. For brevity and simplicity, the following uses one tail CS-shared sub-DAC cell as an example of the proposed tail CS-shared sub-DAC. In other words, a tail CS-shared sub-DAC cell is a basic unit of a tail CS-shared sub-DAC. Hence, any sub-DAC using the proposed tail CS-shared sub-DAC cell falls within the scope of the present invention.

The main difference between the tail CS-shared sub-DACs 107 and 207 is the implementation of signal path circuits 210, 212. Like the signal path circuit 110, the signal path circuit 210 has the clock switch circuit 118 and the data switch circuit 116 series-connected between the shared current source 109 and the data output port (Outp, Outn). However, regarding the signal path circuit 210, the clock switch circuit 118 is coupled between the shared current source 109 and the data switch circuit 116, and the data switch circuit 116 is coupled between the clock switch circuit 118 and the data output port (Outp, Outn). Like the signal path circuit 112, the signal path circuit 212 has the clock switch circuit 122 and the data switch circuit 120 series-connected between the shared current source 109 and the data output port (Outp, Outn). However, regarding the signal path circuit 212, the clock switch circuit 122 is coupled between the shared current source 109 and the data switch circuit 120, and the data switch circuit 120 is coupled between the clock switch circuit 122 and the data output port (Outp, Outn). Regarding the embodiment shown in FIG. 2, the clock switch circuit 118/122 is close to the shared current source 109, while the data switch circuit 116/120 is close to the data output port (Outp, Outn).

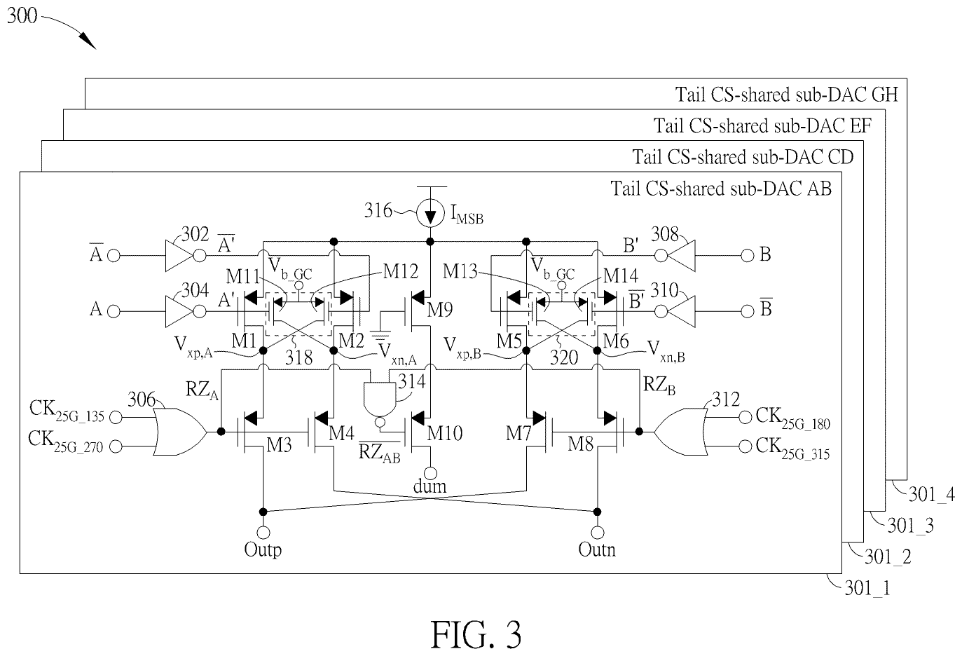

FIG. 3 is a diagram illustrating a first TI-DAC using multiple tail CS-shared sub-DACs according to an embodiment of the present invention. The TI-DAC 300 includes 4 tail CS-shared sub-DACs 301_1, 301_2, 301_3, 301_4. For example, the TI-DAC 300 is an 8b 200 GSPs eight-channel TI-DAC having four 8b 25GSPs tail CS-shared sub-DACs 301_1, 301_2, 301_3, 301_4 for dealing with digital-to-analog conversion of input data A, B, C, D, E, F, G, H, where each of the tail CS-shared sub-DACs 301_1, 301_2, 301_3, 301_4 includes two sub-DACs sharing the same current source. As shown in FIG. 3, the tail CS-shared sub-DAC (labeled by “Tail CS-shared sub-DAC AB”) 301_1 includes sub-DACs (which can be used for dealing with digital-to-analog conversion of input data A and B) that share the same current source, the tail CS-shared sub-DAC (labeled by “Tail CS-shared sub-DAC CD”) 301_2 includes sub-DACs (which can be used for dealing with digital-to-analog conversion of input data C and D) that share the same current source, the tail CS-shared sub-DAC (labeled by “Tail CS-shared sub-DAC EF”) 301_3 includes sub-DACs (which can be used for dealing with digital-to-analog conversion of input data E and F) that share the same current source, and the tail CS-shared sub-DAC (labeled by “Tail CS-shared sub-DAC GH”) 301_4 includes sub-DACs (which can be used for dealing with digital-to-analog conversion of input data G and H) that share the same current source. The tail CS-shared sub-DACs 301_1, 301_2, 301_3, 301_4 employ the same tail CS-shared sub-DAC architecture, but receive different input data and clocks. For brevity and simplicity, only the circuit design of the tail CS-shared sub-DAC 301_1 is illustrated in FIG. 3. Specifically, for better comprehension of technical features of the present invention, only one DAC cell of the tail CS-shared sub-DAC 301_1 is illustrated. In practice, the tail CS-shared sub-DAC 301_1 may include multiple DAC cells (e.g., current cells) jointly used for converting one 8b symbol into an analog output and outputting the analog output within one UI (1 UI=5 ps).

In this embodiment, the circuit design of the tail CS-shared sub-DAC 301_1 is based on the circuit design of the DAC cell shown in FIG. 1. The tail CS-shared sub-DAC 301_1 has one signal path circuit including a data switch circuit (which is formed by transistors M1 and M2) and a clock switch circuit (which is formed by transistors M3 and M4), another signal path circuit including a data switch circuit (which is formed by transistors M5 and M6) and a clock switch circuit (which is formed by transistors M7 and M8), and one RZ path circuit formed by transistors M9 and M10. The signal path circuits and the RZ path circuit share the same current source (i.e., tail current source) 316 that is configured to provide a constant current I_{MSB}.

By way of example, but not limitation, all of the transistors M1-M10 may be implemented using P-channel metal-oxide-semiconductor (PMOS) transistors. The transistors M1, M2, M5, M6 (i.e., data switches) and the transistors M3, M4, M7, M8 (i.e., clock switches) may be configured to operate in the linear region (also called triode region) for larger headroom. The transistor M1 has a control terminal (e.g., gate), a first connection terminal (e.g., source), and a second connection terminal (e.g., drain), where the control terminal (e.g., gate) is configured to receive a control signal A′, and the first connection terminal (e.g., source) is coupled to the shared current source 316. The transistor M2 has a control terminal (e.g., gate), a first connection terminal (e.g., source), and a second connection terminal (e.g., drain), where the control terminal (e.g., gate) is configured to receive a control signal Ā′, and the first connection terminal (e.g., source) is coupled to the shared current source 316. In this embodiment, the control signals A′ and Ā′ are data-dependent signals, and the control signal Ā′ is complementary to the control signal A′.

The transistor M3 has a control terminal (e.g., gate), a first connection terminal (e.g., source), and a second connection terminal (e.g., drain), where the control terminal (e.g., gate) is configured to receive a control signal RZ_{A}, the first connection terminal (e.g., source) is coupled to the second connection terminal (e.g., drain) of the transistor M1, and the second connection terminal (e.g., drain) is coupled to a positive data output node Outp of the data output port (Outp, Outn). The transistor M4 has a control terminal (e.g., gate), a first connection terminal (e.g., source), and a second connection terminal (e.g., drain), where the control terminal (e.g., gate) is configured to receive the control signal RZ_{A}, the first connection terminal (e.g., source) is coupled to the second connection terminal (e.g., drain) of the transistor M2, and the second connection terminal (e.g., drain) is coupled to a negative data output node Outn of the data output port (Outp, Outn).

The transistor M5 has a control terminal (e.g., gate), a first connection terminal (e.g., source), and a second connection terminal (e.g., drain), where the control terminal (e.g., gate) is configured to receive a control signal B′, and the first connection terminal (e.g., source) is coupled to the shared current source 316. The transistor M6 has a control terminal (e.g., gate), a first connection terminal (e.g., source), and a second connection terminal (e.g., drain), where the control terminal (e.g., gate) is configured to receive a control signal B̅′, and the first connection terminal (e.g., source) is coupled to the shared current source 316. In this embodiment, the control signals B′ and B̅′ are data-dependent signals, and the control signal B̅′ is complementary to the control signal B′.

The transistor M7 has a control terminal (e.g., gate), a first connection terminal (e.g., source), and a second connection terminal (e.g., drain), where the control terminal (e.g., gate) is configured to receive a control signal RZ_{B}, the first connection terminal (e.g., source) is coupled to the second connection terminal (e.g., drain) of the transistor M5, and the second connection terminal (e.g., drain) is coupled to the positive data output node Outp of the data output port (Outp, Outn). The transistor M8 has a control terminal (e.g., gate), a first connection terminal (e.g., source), and a second connection terminal (e.g., drain), where the control terminal (e.g., gate) is configured to receive the control signal RZ_{B}, the first connection terminal (e.g., source) is coupled to the second connection terminal (e.g., drain) of the transistor M6, and the second connection terminal (e.g., drain) is coupled to the negative data output node Outn of the data output port (Outp, Outn).

The transistor M9 has a control terminal (e.g., gate), a first connection terminal (e.g., source), and a second connection terminal (e.g., drain), where the control terminal (e.g., gate) is tied to a reference voltage (e.g., ground voltage), and the first connection terminal (e.g., source) is coupled to the shared current source 316.

The transistor M10 has a control terminal (e.g., gate), a first connection terminal (e.g., source), and a second connection terminal (e.g., drain), where the control terminal (e.g., gate) is configured to receive an RZ control signal R̅Z̅_̅{̅A̅B̅}̅, the first connection terminal (e.g., source) is coupled to the second connection terminal (e.g., drain) of the transistor M9, and the second connection terminal (e.g., drain) is coupled to the dummy output node dum.

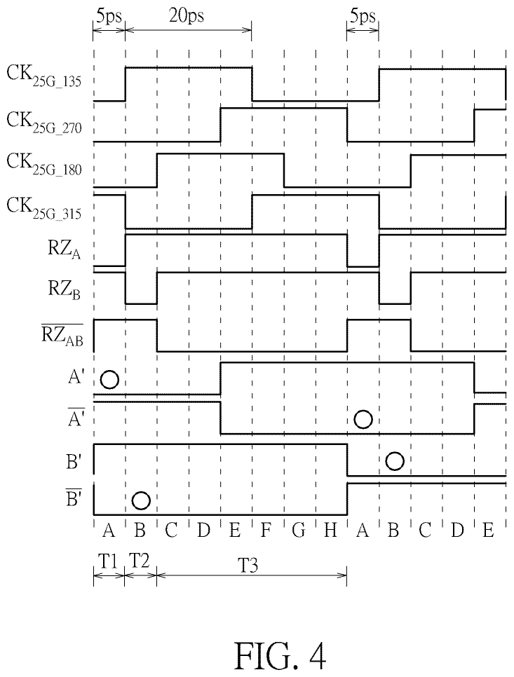

The tail CS-shared sub-DAC 301_1 further includes logic circuits 302, 304, 306, 308, 310, 312, 314 that are configured to generate control signals acting as switch control signals of MOS switches included in the tail CS-shared sub-DAC 301_1. FIG. 4 is a diagram illustrating waveforms of clocks and control signals used by the tail CS-shared sub-DAC 301_1 according to an embodiment of the present invention. One input data A to be converted by the tail CS-shared sub-DAC 301_1 includes two data signals A and Ā, where the data signal Ā is complementary to the data signal A. The other input data B to be converted by the tail CS-shared sub-DAC 301_1 includes two data signals B and B̅, where the data signal B̅ is complementary to the data signal B. The logic circuit 302 is configured to perform a logic operation (e.g., NOT operation) upon the data signal A to generate the control signal A′. The logic circuit 304 is configured to perform a logic operation (e.g., NOT operation) upon the data signal Ā to generate the control signal Ā′. The logic circuit 308 is configured to perform a logic operation (e.g., NOT operation) upon the data signal B to generate the control signal B′. The logic circuit 310 is configured to perform a logic operation (e.g., NOT operation) upon the data signal B̅ to generate the control signal B̅′. It should be noted that each of the data signals A, B and the associated control signals A′, Ā′, B′, B̅′ has a period equal to 8 UI (i.e., 40 ps).

The tail CS-shared sub-DAC 301_1 receives four clocks CK_{25G_135}, CK_{25G_180}, CK_{25G_270}, CK_{25G_315} from a clock generator circuit (e.g., clock generator circuit 104 shown in FIG. 1), where the clocks CK_{25G_135}, CK_{25G_180}, CK_{25G_270}, CK_{25G_315} have the same frequency but different phases.

The logic circuit 306 is configured to perform a logic operation (e.g., OR operation) upon clocks CK_{25G_135} and CK_{25G_270} to generate the control signal RZ_{A}. The logic circuit 312 is configured to perform a logic operation (e.g., OR operation) upon clocks CK_{25G_180} and CK_{25G_315} to generate the control signal RZ_{B}. The logic circuit 314 is configured to perform a logic operation (e.g., NAND operation) upon the control signals RZ_{A} and RZ_{B} to generate the RZ control signal R̅Z̅_̅{̅A̅B̅}̅. It should be noted that each of the clocks CK_{25G_135}, CK_{25G_180}, CK_{25G_270}, CK_{25G_315} has an 8 UI period and a 50% duty cycle.

In this embodiment, each of the tail CS-shared sub-DACs 301_1, 301_2, 301_3, 301_4 acts as a sequential tail CS-shared sub-DAC. Specifically, the tail CS-shared sub-DACs 301_1, 301_2, 301_3, 301_4 are sequentially active to drive the data output port (Outp, Outn) (particularly, pass the constant current of the current source to a selected data output node of the data output port (Outp, Outn)), and all signal path circuits in each of the tail CS-shared sub-DACs 301_1, 301_2, 301_3, 301_4 are sequentially active to drive the data output port (Outp, Outn) (particularly, pass the constant current of the current source to a selected data output node of the data output port (Outp, Outn)). As shown in FIG. 4, an analog output sequence of A→B→C→D→E→F→G→H→A→B→C→D→E→F→G→H can be achieved by sequential tail CS-shared sub-DACs.

Regarding the tail CS-shared sub-DAC 301_1, one signal path circuit activates a current path between the shared current source 316 and the data output port (Outp, Outn) during a period T1 (T1=1 UI=5 ps), where the data output node selection depends on the input data A=(A, Ā); the other signal path circuit activates a current path between the shared current source 316 and the data output port (Outp, Outn) during a period T2 (T2=1 UI=5 ps)) following the period T1, where the data output node selection depends on the input data B=(B, B̅); and none of the signal path circuits activates a current path between the shared current source 316 and the data output port (Outp, Outn) during a period T3 (T3=6 UI=30 ps) following the period T2.

Specifically, during the period T1, the transistors M3 and M4 (i.e., clock switches of one signal path circuit) are both turned on due to RZ_{A}=0, the transistors M7 and M8 (i.e., clock switches of the other signal path circuit) are both turned off due to RZ_{B}=1, the transistor M1 is turned on due to A′=0, the transistor M2 is turned off due to Ā′=1, and the transistor M10 is turned off due to R̅Z̅_̅{̅A̅B̅}̅=1. Hence, during the period T1, the constant current I_{MSB} is provided to the data output node Outp through a current path (i.e., signal path of A) activated by transistors M1 and M3.

During the period T2, the transistors M3 and M4 (i.e., clock switches of one signal path circuit) are both turned off due to RZ_{A}=1, the transistors M7 and M8 (i.e., clock switches of the other signal path circuit) are both turned on due to RZ_{B}=0, the transistor M5 is turned off due to B′=1, the transistor M6 is turned on due to B̅′=0, and the transistor M10 is turned off due to R̅Z̅_̅{̅A̅B̅}̅=1. Hence, during the period T2, the constant current I_{MSB} is provided to the data output node Outn through a current path (i.e., signal path of B) activated by transistors M6 and M8.

During the period T3, the transistors M3 and M4 (i.e., clock switches of one signal path circuit) are both turned off due to RZ_{A}=1, the transistors M7 and M8 (i.e., clock switches of the other signal path circuit) are both turned off due to RZ_{B}=1, and the transistor M10 is turned on due to R̅Z̅_̅{̅A̅B̅}̅=0. Hence, during the period T3, the constant current I_{MSB} is provided to the dummy output node dum through an RZ path activated by transistors M9 and M10.

Since the same current source 316 is shared between two sub-DACs (which can be used for dealing with digital-to-analog conversion of input data A and B), static power and area can be saved. During the period T3 in which the transistors M3, M4, M7 and M8 (i.e., clock switches) are turned off, the input data A may change it state (e.g., 0→1 or 1→0), resulting in the feedthrough charge stored at V_{xp,A}/V_{xn,A}, and the input data B may change it state (e.g., 0→1 or 1→0), resulting in the feedthrough charge stored at V_{xp,B}/V_{xn,B}. The feedthrough charge will be released after the transistors M3, M4, M7 and M8 (i.e., clock switches) are turned on again, which affects the actual output current passing through the current path (i.e., signal path) selected by the input data A and B. To address the code-dependent non-linearity issue, the present invention further proposes adding glitch cancellation circuits 318 and 320 to the tail CS-shared sub-DAC 301_1.

The glitch cancellation circuit 318 is configured to apply glitch cancellation to the second connection terminal (e.g., drain) of the transistor M1 and the second connection terminal (e.g., drain) of the transistor M2. For example, the glitch cancellation circuit 318 includes transistors (e.g., PMOS transistors) M11 and M12. The transistor M11 has a control terminal (e.g., gate), a first connection terminal (e.g., source), and a second connection terminal (e.g., drain), where the control terminal (e.g., gate) is configured to receive the control signal A′ (which is also received by the control terminal of the transistor M1), the first connection terminal (e.g., source) is coupled to a reference voltage V_{b_GC}, and the second connection terminal (e.g., drain) is coupled to the second connection terminal (e.g., drain) of the transistor M2. The transistor M12 has a control terminal (e.g., gate), a first connection terminal (e.g., source), and a second connection terminal (e.g., drain), where the control terminal (e.g., gate) is configured to receive the control signal Ā′ (which is also received by the transistor M2), the first connection terminal (e.g., source) is coupled to the reference voltage V_{b_GC}, and the second connection terminal (e.g., drain) is coupled to the second connection terminal (e.g., drain) of the transistor M1. The transistors M1 and M12 have second connection terminals connected to the same node V_{xp,A}, but ON/OFF states of the transistors M1 and M12 are controlled by complementary control signals A′ and Ā′. Hence, induced glitch effects with opposite polarities can be cancelled out at the node V_{xp,A}. Similarly, the transistors M2 and M11 have second connection terminals connected to the same node V_{xn,A}, but ON/OFF states of the transistors M2 and M11 are controlled by complementary control signals Ā′ and A′. Hence, induced glitch effects with opposite polarities can be cancelled out at the node V_{xn,A}.

The glitch cancellation circuit 320 is configured to apply glitch cancellation to the second connection terminal (e.g., drain) of the transistor M5 and the second connection terminal (e.g., drain) of the transistor M6. For example, the glitch cancellation circuit 320 includes transistors (e.g., PMOS transistors) M13 and M14. The transistor M13 has a control terminal (e.g., gate), a first connection terminal (e.g., source), and a second connection terminal (e.g., drain), where the control terminal (e.g., gate) is configured to receive the control signal B′ (which is also received by the transistor M5), the first connection terminal (e.g., source) is coupled to the reference voltage V_{b_GC}, and the second connection terminal (e.g., drain) is coupled to the second connection terminal (e.g., drain) of the transistor M6. The transistor M14 has a control terminal (e.g., gate), a first connection terminal (e.g., source), and a second connection terminal (e.g., drain), where the control terminal (e.g., gate) is configured to receive the control signal B̅′ (which is also received by the transistor M6), the first connection terminal (e.g., source) is coupled to the reference voltage V_{b_GC}, and the second connection terminal (e.g., drain) is coupled to the second connection terminal (e.g., drain) of the transistor M5. The transistors M5 and M14 have second connection terminals connected to the same node V_{xp,B}, but ON/OFF states of the transistors M5 and M14 are controlled by complementary control signals B′ and B̅′. Hence, induced glitch effects with opposite polarities can be cancelled out at the node V_{xp,B}. Similarly, the transistors M6 and M13 have second connection terminals connected to the same node V_{xn,B}, but ON/OFF states of the transistors M6 and M13 are controlled by complementary control signals B̅′ and B′. Hence, induced glitch effects with opposite polarities can be cancelled out at the node V_{xn,B}.

As shown in FIG. 3, the TI-DAC 300 includes 4 tail CS-shared sub-DACs 301_1, 301_2, 301_3, 301_4 to support 8 channels. In some embodiments of the present invention, each tail CS-shared sub-DAC in a TI-DAC may be modified to support re-configurability. In this way, a reconfigurable TI-DAC can be used to meet different digital-to-conversion requirements.

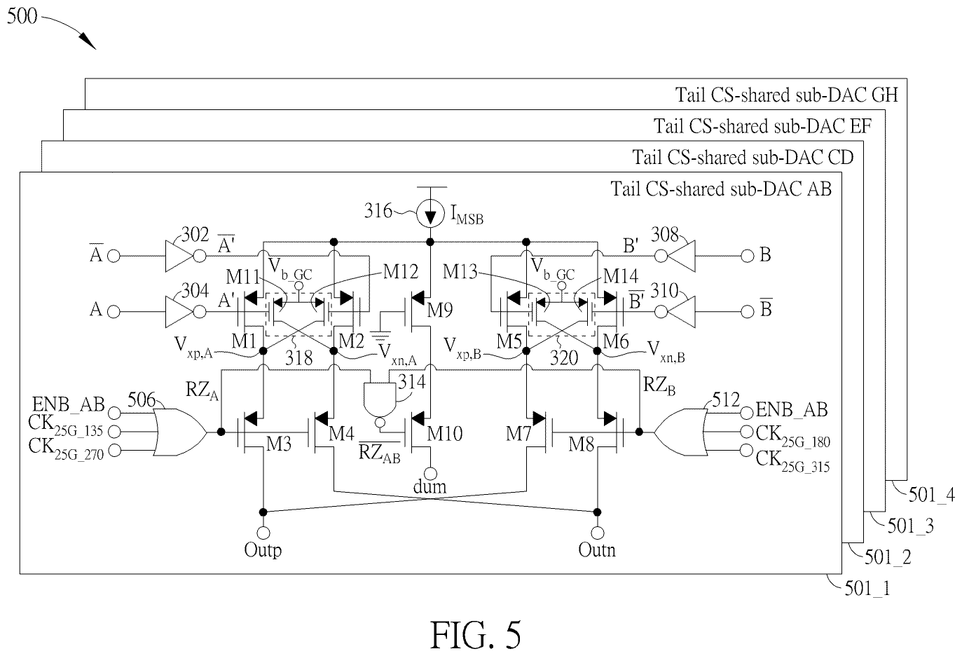

FIG. 5 is a diagram illustrating a second TI-DAC using multiple tail CS-shared sub-DACs according to an embodiment of the present invention. The TI-DAC 500 includes 4 tail CS-shared sub-DACs 501_1, 501_2, 501_3, 501_4. As shown in FIG. 5, the tail CS-shared sub-DAC (labeled by “Tail CS-shared sub-DAC AB”) 501_1 includes sub-DACs (which can be used for dealing with digital-to-analog conversion of input data A and B, if enabled) that share the same current source, the tail CS-shared sub-DAC (labeled by “Tail CS-shared sub-DAC CD”) 501_2 includes sub-DACs (which can be used for dealing with digital-to-analog conversion of input data C and D, if enabled) that share the same current source, the tail CS-shared sub-DAC (labeled by “Tail CS-shared sub-DAC EF”) 501_3 includes sub-DACs (which can be used for dealing with digital-to-analog conversion of input data E and F, if enabled) that share the same current source, and the tail CS-shared sub-DAC (labeled by “Tail CS-shared sub-DAC GH”) 501_4 includes sub-DACs (which can used for dealing with digital-to-analog conversion of input data G and H, if enabled) that share the same current source. The tail CS-shared sub-DACs 501_1, 501_2, 501_3, 501_4 employ the same tail CS-shared sub-DAC architecture. For brevity and simplicity, only the circuit design of the tail CS-shared sub-DAC 501_1 is illustrated in FIG. 5. Specifically, for better comprehension of technical features of the present invention, only one DAC cell of the tail CS-shared sub-DAC 501_1 is illustrated. In practice, the tail CS-shared sub-DAC 501_1 may include multiple DAC cells (e.g., current cells) jointly used for converting one 8b symbol into an analog output and outputting the analog output within one UI (1 UI=5 ps).

The main difference between the tail CS-shared sub-DAC 501_1/501_2/501_3/501_4 shown in FIG. 5 and the tail CS-shared sub-DACs 301_1/301_2/301_3/301_4 shown in FIG. 3 is that the tail CS-shared sub-DAC 501_1/501_2/501_3/501_4 supports re-configurability. For example, the tail CS-shared sub-DAC 501_1 includes a logic circuit 506 configured to generate the control signal RZ_{A} and a logic circuit 512 configured to generate the control signal RZ_{B}. In addition to the clocks CK_{25G_135} and CK_{25G_270} (or CK_{25G_180} and CK_{25G_315}), the logic circuit 506 (or 512) further receives an enable signal ENB_AB which is set to control whether the tail CS-shared sub-DAC 501_1 is enabled. Specifically, the logic circuit 506 is configured to perform a logic operation (e.g., OR operation) upon the enable signal ENB_AB and the clocks CK_{25G_135} and CK_{25G_270} to generate the control signal RZ_{A}, and the logic circuit 512 is configured to perform a logic operation (e.g., OR operation) upon the enable signal ENB_AB and the clocks CK_{25G_180} and CK_{25G_315} to generate the control signal RZ_{B}. When the enable signal ENB_AB is set by a logic high level (i.e., ENB_AB=1), the control signal RZ_{A} has a logic high level (i.e., RZ_{A}=1) regardless of the clocks CK_{25G_135} and CK_{25G_270}, and the control signal RZ_{B} has a logic high level (i.e., RZ_{B}=1) regardless of the clocks CK_{25G_180} and CK_{25G_315}. In this way, the transistors M3, M4, M7, M8 (i.e., clock switches) are all turned off, thereby disabling the tail CS-shared sub-DAC 501_1. When the enable signal ENB_AB is set by a logic low level (i.e., ENB_AB=0), the control signal RZ_{A} is set by ORing the clocks CK_{25G_135} and CK_{25G_270}, and the control signal RZ_{B} is set by ORing the clocks CK_{25G_180} and CK_{25G_315}. In this way, the transistors M3, M4, M7, M8 (i.e., clock switches) are controlled by normal control signals RZ_{A} and RZ_{B}, thereby enabling the tail CS-shared sub-DAC 501_1.

The tail CS-shared sub-DACs 501_1, 501_2, 501_3, 501_4 receive enable signals ENB_AB, ENB_CD, ENB_EF, ENB_GH, respectively. With proper settings of enable signals ENB_AB, ENB_CD, ENB_EF, ENB_GH, the same TI-DAC 500 can be re-configured to support any of different digital-to-analog conversion requirements. Settings of enable signals ENB_AB, ENB_CD, ENB_EF, ENB_GH and clocks CK_{25G_0}, CK_{25G_45}, CK_{25G_90}, CK_{25G_135}, CK_{25G_180}, CK_{25G_225}, CK_{25G_270}, CK_{25G_315} for different channel numbers 8X, 4X, 2X are listed in the following table. However, this is for illustrative purposes only, and is not meant to be a limitation of the present invention.

TABLE 1

| Control | 8X | 4X | 2X |
|---|---|---|---|
| ENB_AB | 0 | 0 | 0 |
| ENB_CD | 0 | 1 | 1 |
| ENB_EF | 0 | 0 | 1 |
| ENB_GH | 0 | 1 | 1 |
| CK_{25G}_{_{—}}₀ | 0° | 90° | 90° |
| CK_{25G}_{_{—}}₄₅ | 45° | 0° | 270° |
| CK_{25G}_{_{—}}₉₀ | 90° | 90° | 90° |
| CK_{25G}_{_{—}}₁₃₅ | 135° | 180° | 270° |
| CK_{25G}_{_{—}}₁₈₀ | 180° | 270° | 90° |
| CK_{25G}_{_{—}}₂₂₅ | 225° | 180° | 270° |
| CK_{25G}_{_{—}}₂₇₀ | 270° | 270° | 270° |
| CK_{25G}_{_{—}}₃₁₅ | 315° | 0° | 90° |

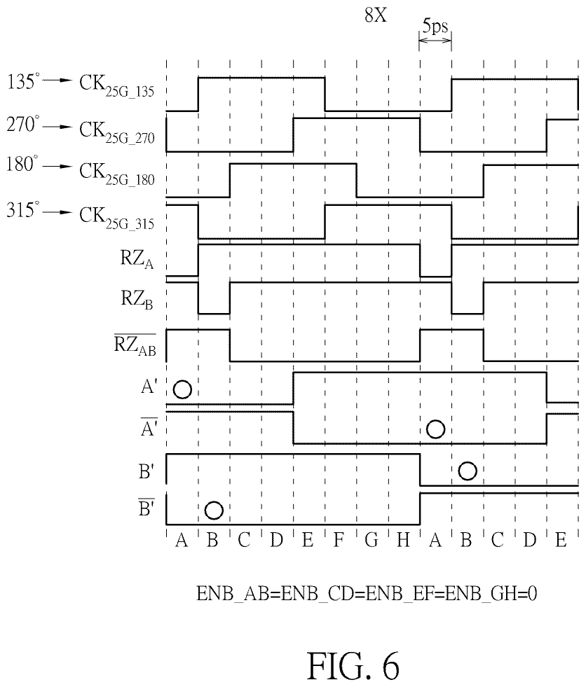

If all of the 8b 25 GSps tail CS-shared sub-DACs 501_1, 501_2, 501_3, 501_4 are enabled by ENB_AB=ENB_CD=ENB_EF=ENB_GH=0, the TI-DAC 500 is configured to act as an 8b 200 GSps eight-channel TI-DAC, and 8-phase clocks (0°, 45°, 90°, 135°, 180°, 225°, 270°, 315°) can be used for generating control signals needed by the enabled tail CS-shared sub-DACs 501_1, 501_2, 501_3, 501_4. FIG. 6 is a diagram illustrating settings of clocks used by the tail CS-shared sub-DAC 501_1 that is enabled under ENB_AB=ENB_CD=ENB_EF=ENB_GH=0 according to an embodiment of the present invention.

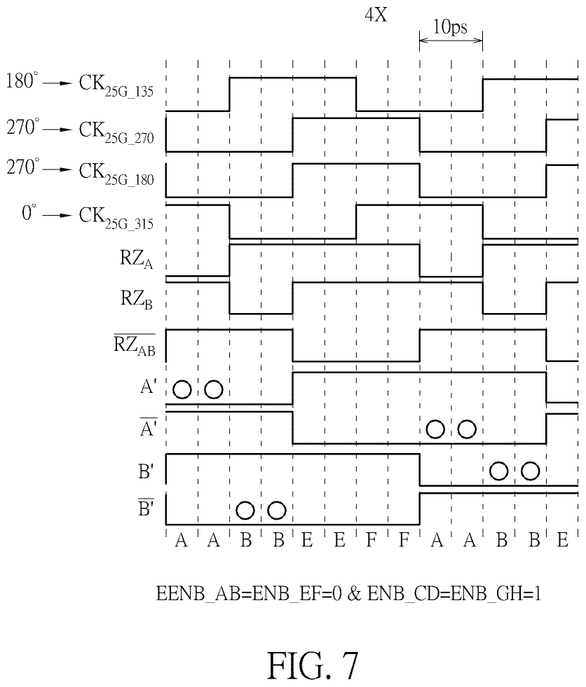

If only two of the 8b 25 GSps tail CS-shared sub-DACs 501_1, 501_2, 501_3, 501_4 are enabled by ENB_AB=ENB_EF=0 & ENB_CD=ENB_GH=1, the TI-DAC 500 is configured to act as an 8b 100 GSps four-channel TI-DAC, and 4-phase clocks (0°, 90°, 180°, 270°) are used for generating control signals needed by the enabled tail CS-shared sub-DACs 501_1 and 501_3. FIG. 7 is a diagram illustrating settings of clocks used by the tail CS-shared sub-DAC 501_1 that is enabled under ENB_AB=ENB_EF=0 & ENB_CD=ENB_GH=1 according to an embodiment of the present invention. Specifically, the clock input CK_{25G_135} specified in the circuit design of the tail CS-shared sub-DACs 501_1 is re-configured to receive the clock CK_{25G_180}, the clock input CK_{25G_180} specified in the circuit design of the tail CS-shared sub-DACs 501_1 is re-configured to receive the clock CK_{25G_270}, and the clock input CK_{25G_315} specified in the circuit design of the tail CS-shared sub-DACs 501_1 is re-configured to receive the clock CK_{25G_0}.

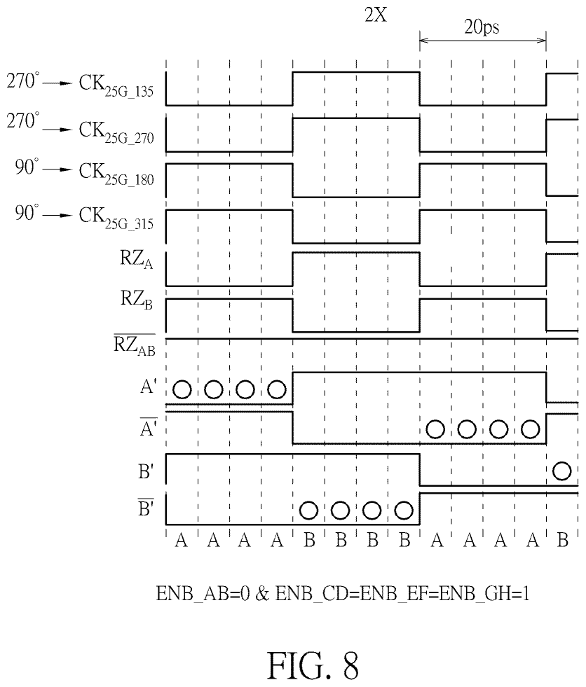

If only one of the 8b 25 GSps tail CS-shared sub-DACs 501_1, 501_2, 501_3, 501_4 is enabled by ENB_AB=0 & ENB_CD=ENB_EF=ENB_GH=1, the TI-DAC 500 is configured to act as an 8b 50 GSps two-channel TI-DAC, and 2-phase clocks (90°, 270°) are used for generating control signals needed by the enabled tail CS-shared sub-DAC 501_1. FIG. 8 is a diagram illustrating settings of clocks used by the tail CS-shared sub-DAC 501_1 that is enabled under ENB_AB=0 & ENB_CD=ENB_EF=ENB_GH=1 according to an embodiment of the present invention. Specifically, the clock input CK_{25G_135} specified in the circuit design of the tail CS-shared sub-DACs 501_1 is re-configured to receive the clock CK_{25G_270}, the clock input CK_{25G_180} specified in the circuit design of the tail CS-shared sub-DACs 501_1 is re-configured to receive the clock CK_{25G_90}, and the clock input CK_{25G_315} specified in the circuit design of the tail CS-shared sub-DACs 501_1 is re-configured to receive the clock CK_{25G_90}.

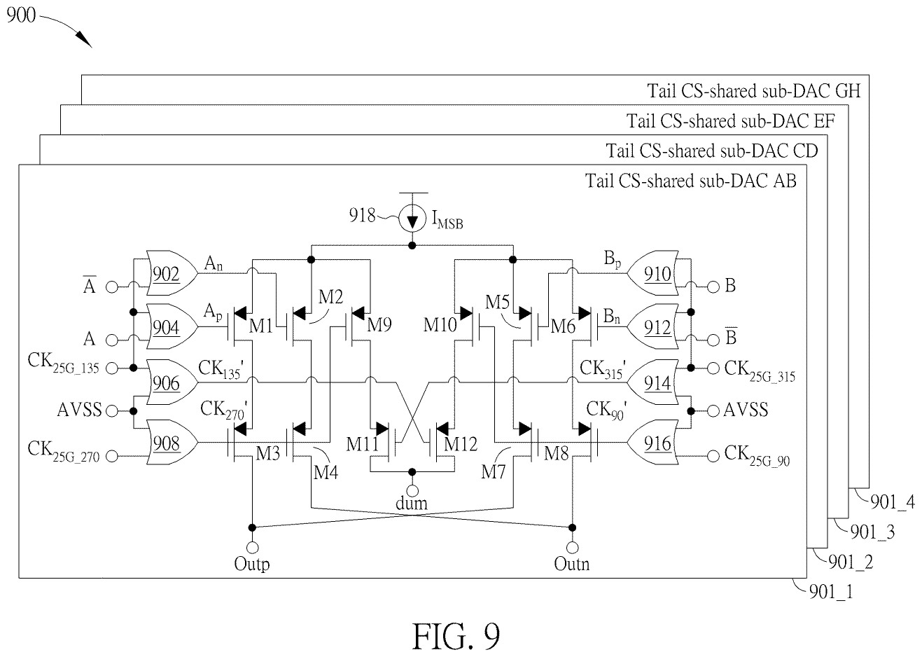

FIG. 9 is a diagram illustrating a third TI-DAC using multiple tail CS-shared sub-DACs according to an embodiment of the present invention. The TI-DAC 900 includes 4 tail CS-shared sub-DACs 901_1, 901_2, 901_3, 901_4. For example, the TI-DAC 900 is an 8b 200 GSPs eight-channel TI-DAC having four 8b 25GSPs tail CS-shared sub-DACs 901_1, 901_2, 901_3, 901_4 for dealing with digital-to-analog conversion of input data A, B, C, D, E, F, G, H, where each of the tail CS-shared sub-DACs 901_1, 901_2, 901_3, 901_4 includes two sub-DACs that share the same current source. As shown in FIG. 9, the tail CS-shared sub-DAC (labeled by “Tail CS-shared sub-DAC AB”) 901_1 includes sub-DACs (which can be used for dealing with digital-to-analog conversion of input data A and B) that share the same current source, the tail CS-shared sub-DAC (labeled by “Tail CS-shared sub-DAC CD”) 901_2 includes sub-DACs (which can be used for dealing with digital-to-analog conversion of input data C and D) that share the same current source, the tail CS-shared sub-DAC (labeled by “Tail CS-shared sub-DAC EF”) 901_3 includes sub-DACs (which can be used for dealing with digital-to-analog conversion of input data E and F) that share the same current source, and the tail CS-shared sub-DAC (labeled by “Tail CS-shared sub-DAC GH”) 901_4 includes sub-DACs (which can be used for dealing with digital-to-analog conversion of input data G and H) that share the same current source. The tail CS-shared sub-DACs 901_1, 901_2, 901_3, 901_4 employ the same tail CS-shared sub-DAC architecture, but receive different input data and clocks. For brevity and simplicity, only the circuit design of the tail CS-shared sub-DAC 901_1 is illustrated in FIG. 9. Specifically, for better comprehension of technical features of the present invention, only one DAC cell of the tail CS-shared sub-DAC 901_1 is illustrated. In practice, the tail CS-shared sub-DAC 901_1 may include multiple DAC cells (e.g., current cells) jointly used for converting one 8b symbol into an analog output and outputting the analog output within one UI (1 UI=5 ps).

In this embodiment, the circuit design of the tail CS-shared sub-DAC 901_1 is based on the circuit design of the DAC cell shown in FIG. 1. The tail CS-shared sub-DAC 901_1 has one signal path circuit including a data switch circuit (which is formed by transistors M1 and M2) and a clock switch circuit (which is formed by transistors M3 and M4), another signal path circuit including a data switch circuit (which is formed by transistors M5 and M6) and a clock switch circuit (which is formed by transistors M7 and M8), and one RZ path circuit formed by transistors M9, M10, M11, M12. The signal path circuits and the RZ path circuit share the same current source (i.e., tail current source) 918 that is configured to provide a constant current I_{MSB}.

By way of example, but not limitation, all of the transistors M1-M12 may be implemented using PMOS transistors. The transistors M1, M2, M5, M6 (i.e., data switches) and the transistors M3, M4, M7, M8 (i.e., clock switches) may be configured to operate in the linear region (also called triode region) for larger headroom. The transistor M1 has a control terminal (e.g., gate), a first connection terminal (e.g., source), and a second connection terminal (e.g., drain), where the control terminal (e.g., gate) is configured to receive a control signal Aₚ, and the first connection terminal (e.g., source) is coupled to the shared current source 918. The transistor M2 has a control terminal (e.g., gate), a first connection terminal (e.g., source), and a second connection terminal (e.g., drain), where the control terminal (e.g., gate) is configured to receive a control signal Aₙ, and the first connection terminal (e.g., source) is coupled to the shared current source 918. In this embodiment, the control signals Aₚ and Aₙ are data-dependent signals, but the control signal Aₙ is not complementary to the control signal Aₚ.

The transistor M3 has a control terminal (e.g., gate), a first connection terminal (e.g., source), and a second connection terminal (e.g., drain), where the control terminal (e.g., gate) is configured to receive a control signal CK₂₇₀′, the first connection terminal (e.g., source) is coupled to the second connection terminal (e.g., drain) of the transistor M1, and the second connection terminal (e.g., drain) is coupled to a positive data output node Outp of the data output port (Outp, Outn). The transistor M4 has a control terminal (e.g., gate), a first connection terminal (e.g., source), and a second connection terminal (e.g., drain), where the control terminal (e.g., gate) is configured to receive the control signal CK₂₇₀′, the first connection terminal (e.g., source) is coupled to the second connection terminal (e.g., drain) of the transistor M2, and the second connection terminal (e.g., drain) is coupled to a negative data output node Outn of the data output port (Outp, Outn).

The transistor M5 has a control terminal (e.g., gate), a first connection terminal (e.g., source), and a second connection terminal (e.g., drain), where the control terminal (e.g., gate) is configured to receive a control signal Bₚ, and the first connection terminal (e.g., source) is coupled to the shared current source 918. The transistor M6 has a control terminal (e.g., gate), a first connection terminal (e.g., source), and a second connection terminal (e.g., drain), where the control terminal (e.g., gate) is configured to receive a control signal Bₙ, and the first connection terminal (e.g., source) is coupled to the shared current source 918. In this embodiment, the control signals Bₚ and Bₙ are data-dependent signals, but the control signal Bₙ is not complementary to the control signal Bₙ.

The transistor M7 has a control terminal (e.g., gate), a first connection terminal (e.g., source), and a second connection terminal (e.g., drain), where the control terminal (e.g., gate) is configured to receive a control signal CK₉₀′, the first connection terminal (e.g., source) is coupled to the second connection terminal (e.g., drain) of the transistor M5, and the second connection terminal (e.g., drain) is coupled to the positive data output node Outp of the data output port (Outp, Outn). The transistor M8 has a control terminal (e.g., gate), a first connection terminal (e.g., source), and a second connection terminal (e.g., drain), where the control terminal (e.g., gate) is configured to receive the control signal CK₉₀′, the first connection terminal (e.g., source) is coupled to the second connection terminal (e.g., drain) of the transistor M6, and the second connection terminal (e.g., drain) is coupled to the negative data output node Outn of the data output port (Outp, Outn).

The transistor M9 has a control terminal (e.g., gate), a first connection terminal (e.g., source), and a second connection terminal (e.g., drain), where the control terminal (e.g., gate) is configured to receive the control signal CK₂₇₀′ (which is also received by the transistors M3 and M4), and the first connection terminal (e.g., source) is coupled to the shared current source 918. The transistor M10 has a control terminal (e.g., gate), a first connection terminal (e.g., source), and a second connection terminal (e.g., drain), where the control terminal (e.g., gate) is configured to receive the control signal CK₉₀′ (which is also received by the transistors M7 and M8), and the first connection terminal (e.g., source) is coupled to the shared current source 918. The transistor M11 has a control terminal (e.g., gate), a first connection terminal (e.g., source), and a second connection terminal (e.g., drain), where the control terminal (e.g., gate) is configured to receive a control signal CK₃₁₅′, the first connection terminal (e.g., source) is coupled to the second connection terminal (e.g., drain) of the transistor M9, and the second connection terminal (e.g., drain) is coupled to the dummy output node dum. The transistor M12 has a control terminal (e.g., gate), a first connection terminal (e.g., source), and a second connection terminal (e.g., drain), where the control terminal (e.g., gate) is configured to receive a control signal CK₁₃₅′, the first connection terminal (e.g., source) is coupled to the second connection terminal (e.g., drain) of the transistor M10, and the second connection terminal (e.g., drain) is coupled to the dummy output node dum.

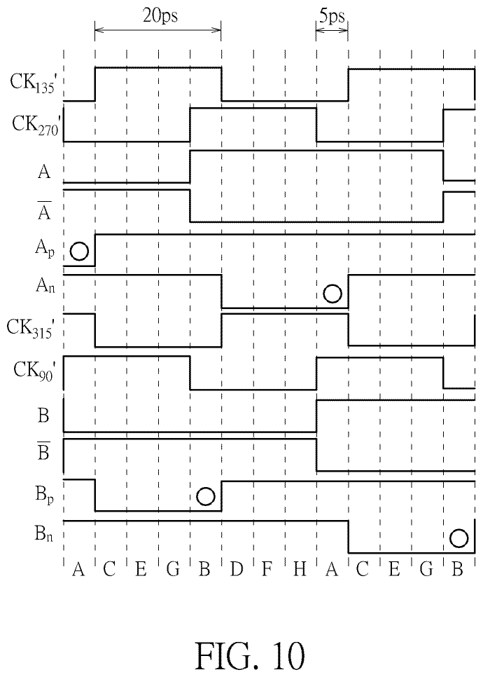

The tail CS-shared sub-DAC 901_1 further includes logic circuits 902, 904, 906, 908, 910, 912, 914, 916 that are configured to generate control signals acting as switch control signals of MOS switches included in the tail CS-shared sub-DAC 901_1. FIG. 10 is a diagram illustrating waveforms of input data, clocks and control signals used by the tail CS-shared sub-DAC 901_1 according to an embodiment of the present invention. One input data A to be converted by the tail CS-shared sub-DAC 901_1 includes two data signals A and Ā, where the data signal Ā is complementary to the data signal A. The other input data B to be converted by the tail CS-shared sub-DAC 901_1 includes two data signals B and B̅, where the data signal B̅ is complementary to the data signal B. It should be noted that each of the data signals A, B has a period equal to 8 UI (i.e., 40 ps). The tail CS-shared sub-DAC 901_1 receives four clocks CK_{25G_90}, CK_{25G_135}, CK_{25G_270}, CK_{25G_315} from a clock generator circuit (e.g., clock generator circuit 104 shown in FIG. 1), where the clocks CK_{25G_90}, CK_{25G_135}, CK_{25G_270}, CK_{25G_315} have the same frequency but different phases. It should be noted that each of the clocks CK_{25G_90}, CK_{25G_135}, CK_{25G_270}, CK_{25G_315} has an 8 UI period and a 50% duty cycle.

The logic circuit 904 is configured to perform a logic operation (e.g., OR operation) upon the data signal A and the clock CK_{25G_135} to generate the control signal Aₚ. The logic circuit 902 is configured to perform a logic operation (e.g., OR operation) upon the data signal Ā and the clock CK_{25G_135} to generate the control signal Aₙ. The logic circuit 910 is configured to perform a logic operation (e.g., OR operation) upon the data signal B and the clock CK_{25G_315} to generate the control signal Bp. The logic circuit 912 is configured to perform a logic operation (e.g., OR operation) upon the data signal B̅ and the clock CK_{25G_315} to generate the control signal Bₙ.

The logic circuit 906 is configured to perform a logic operation (e.g., OR operation) upon the clock CK_{25G_135} and a reference voltage (e.g., analog ground voltage AVSS) to generate the control signal CK₁₃₅′. The logic circuit 914 is configured to perform a logic operation (e.g., OR operation) upon the clock CK_{25G_315} and the reference voltage (e.g., analog ground voltage AVSS) to generate the control signal CK₃₁₅′. The logic circuit 908 is configured to perform a logic operation (e.g., OR operation) upon the clock CK_{25G_270} and the reference voltage (e.g., analog ground voltage AVSS) to generate the control signal CK₂₇₀′. The logic circuit 916 is configured to perform a logic operation (e.g., OR operation) upon the clock CK_{25G_90} and the reference voltage (e.g., analog ground voltage AVSS) to generate the control signal CK₉₀′.

In this embodiment, each of the tail CS-shared sub-DACs 901_1, 901_2, 901_3, 901_4 acts as a non-sequential tail CS-shared sub-DAC. Specifically, the tail CS-shared sub-DACs 901_1, 901_2, 901_3, 901_4 are sequentially active to drive the data output port (Outp, Outn) (particularly, pass the constant current of the current source to a selected data output node of the data output port (Outp, Outn)), and signal path circuits in each of the tail CS-shared sub-DACs 901_1, 901_2, 901_3, 901_4 are non-sequentially active to drive the data output port (Outp, Outn) (particularly, pass the constant current of the current source to a selected data output node of the data output port (Outp, Outn)). Regarding the tail CS-shared sub-DAC 901_1, one signal path circuit activates a current path between the shared current source 918 and the data output port (Outp, Outn) during a first period, where the data output node selection depends on the input data A; and the other signal path circuit activates a current path between the shared current source 918 and the data output port (Outp, Outn) during a second period, where the data output node selection depends on the input data B. The first period and the second period occupied by the tail CS-shared sub-DAC 901_1 are non-sequential periods. That is, the first period and the second period occupied by the tail CS-shared sub-DAC 901_1 for driving the data output port (Outp, Outn) are spaced by periods occupied by other tail CS-shared sub-DACs 901_2-902_4 for driving the data output port (Outp, Outn). As shown in FIG. 10, an analog output sequence of A→C→E→G→B→D→F→H→A→C→E→G→B can be achieved by sequential tail CS-shared sub-DACs.

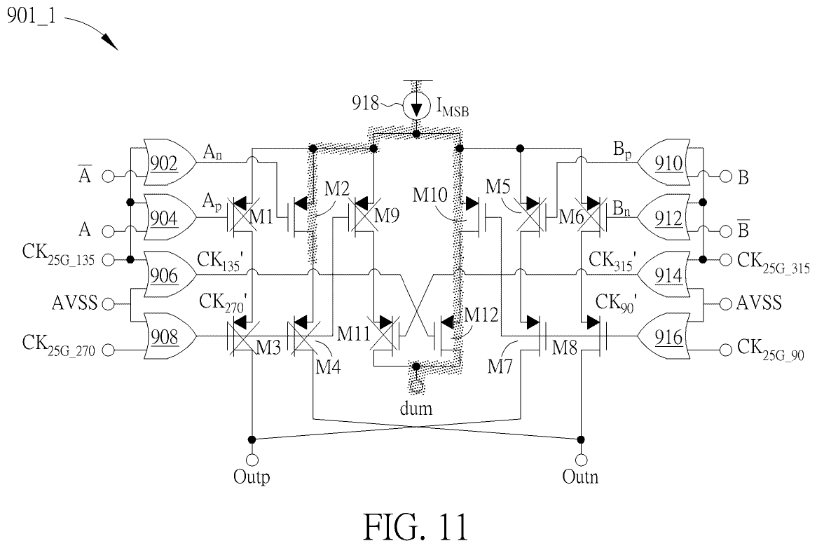

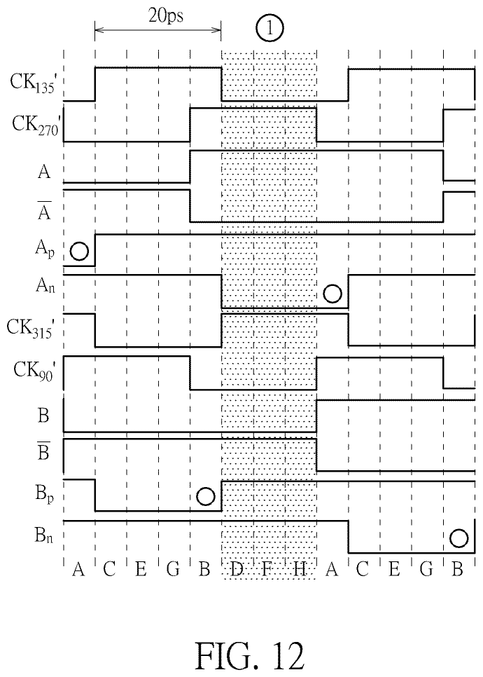

Please refer to FIG. 11 in conjunction with FIG. 12. FIG. 11 is a diagram illustrating an RZ phase (Reset phase of A) of the tail CS-shared sub-DAC 901_1 according to an embodiment of the present invention. FIG. 12 is a diagram illustrating a period (labeled by a circled number 1) in which the tail CS-shared sub-DAC 901_1 operates in the RZ phase (Reset phase of A). The transistors M3, M4 (i.e., clock switches of one signal path circuit) and the transistor M9 are turned off due to CK₂₇₀′=1. The transistors M7, M8 (i.e., clock switches of the other signal path circuit) and the transistor M10 are turned on due to CK₉₀′=0. One of the transistors M1 and M2 (i.e., data switches of one signal path circuit) is turned on, depending upon the input data A=(A, Ā) from which the control signals Aₚ and Aₙ are derived. In this example, the transistor M1 is turned off due to Aₚ=1, and the transistor M2 is turned on due to Aₙ=0. The transistors M5 and M6 (i.e., data switches of the other signal path circuit) are both turned off due to Bₚ=1 and Bₙ=1. The transistor M11 is turned off due to CK₃₁₅′=1. The transistor M12 is turned on due to CK₁₃₅′=0. Hence, during the RZ phase (Reset phase of A), the constant current I_{MSB} is provided to the dummy output node dum through an RZ path activated by the transistors M10 and M12, and an internal node of a current path (i.e., signal path of A) that will be later activated between the shared current source 918 and the data output node Outn is reset in advance through the transistor M2. Since a current cell of the tail CS-shared sub-DAC 901_1) has a reset function for resting an internal node of the current cell, the code-dependent non-linearity can be reduced, and the operation speed can be increased.

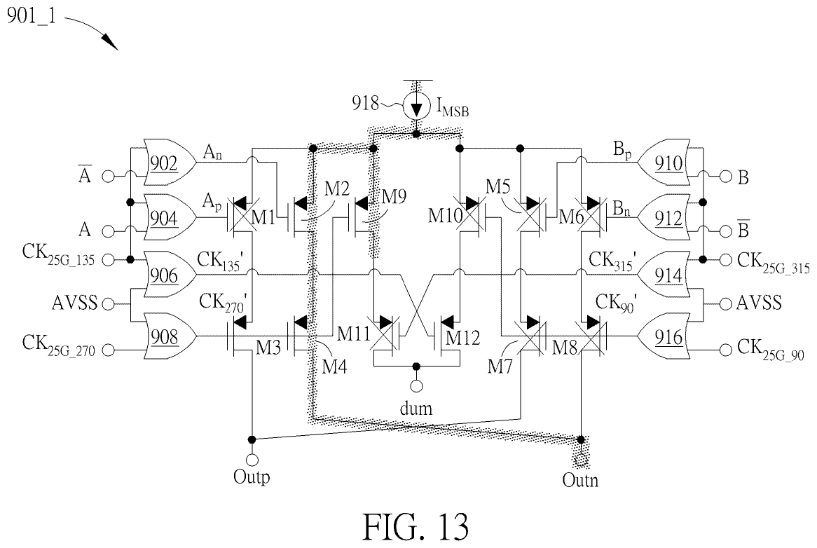

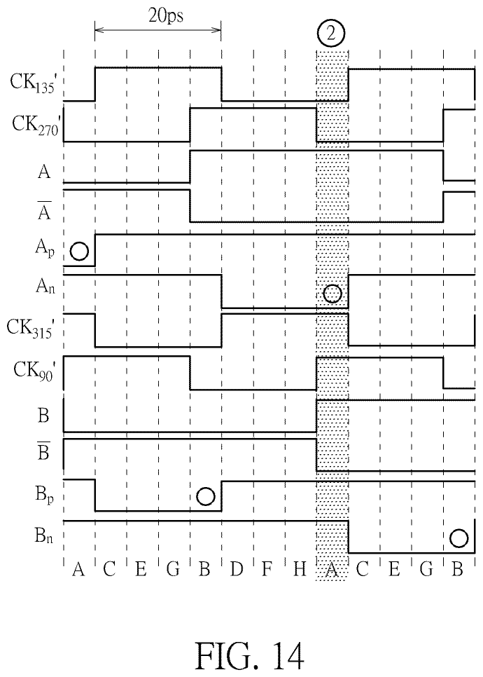

Please refer to FIG. 13 in conjunction with FIG. 14. FIG. 13 is a diagram illustrating a signal phase of A of the tail CS-shared sub-DAC 901_1 according to an embodiment of the present invention. FIG. 14 is a diagram illustrating a period (labeled by a circled number 2) in which the tail CS-shared sub-DAC 901_1 operates in the signal phase of A. The transistors M3, M4 (i.e., clock switches of one signal path circuit) and the transistor M9 are turned on due to CK₂₇₀′=0. The transistors M7, M8 (i.e., clock switches of the other signal path circuit) and the transistor M10 are turned off due to CK₉₀′=1. One of the transistors M1 and M2 (i.e., data switches of one signal path circuit) is turned on, depending upon the input data A=(A, Ā) from which the control signals Aₚ and Aₙ are derived. In this example, the transistor M1 is turned off due to Aₚ=1, and the transistor M2 is turned on due to Aₙ=0. The transistors M5 and M6 (i.e., data switches of the other signal path circuit) are both turned off due to Bₚ=1 and Bₙ=1. The transistor M11 is turned off due to CK₃₁₅′=1. The transistor M12 is turned on due to CK₁₃₅′=0. Hence, the constant current I_{MSB} is provided to the data output node Outn through a current path (i.e., signal path of A) activated by transistors M2 and M4.

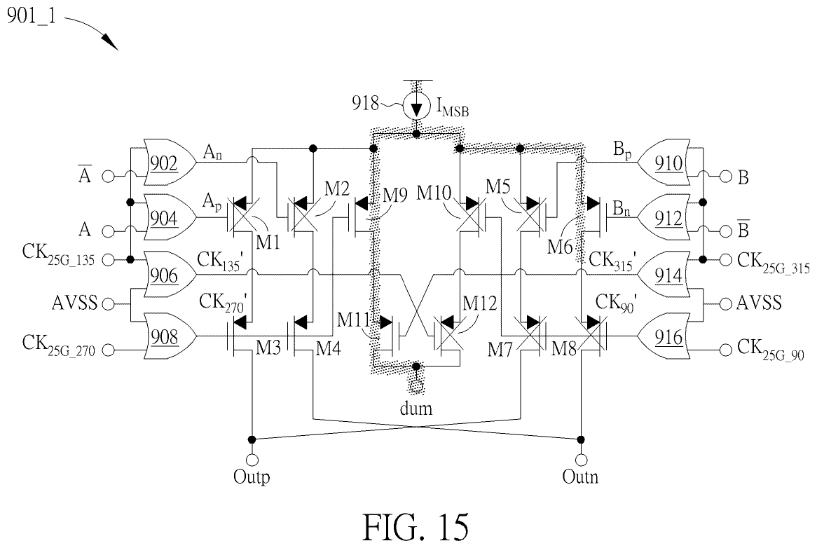

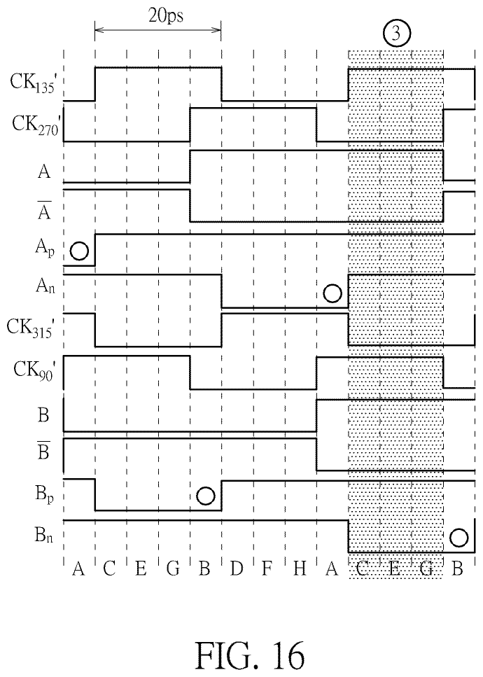

Please refer to FIG. 15 in conjunction with FIG. 16. FIG. 15 is a diagram illustrating an RZ phase (Reset phase of B) of the tail CS-shared sub-DAC 901_1 according to an embodiment of the present invention. FIG. 16 is a diagram illustrating a period (labeled by a circled number 3) in which the tail CS-shared sub-DAC 9011 operates in the RZ phase (Reset phase of B). The transistors M3, M4 (i.e., clock switches of one signal path circuit) and the transistor M9 are turned on due to CK₂₇₀′=0. The transistors M7, M8 (i.e., clock switches of the other signal path circuit) and the transistor M10 are turned off due to CK₉₀′=1. The transistors M1 and M2 (i.e., data switches of one signal path circuit) are both turned off due to Aₚ=1 and Aₙ=1. One of the transistors M5 and M6 (i.e., data switches of the other signal path circuit) is turned on, depending upon the input data B=(B, B̅) from which the control signals Bₚ and Bₙ are derived. In this example, the transistor M5 is turned off due to Bₚ=1, and the transistor M6 is turned on due to Bₙ=0. The transistor M11 is turned on due to CK₃₁₅′=0. The transistor M12 is turned off due to CK₁₃₅′=1. Hence, during the RZ phase (Reset phase of B), the constant current I_{MSB} is provided to the dummy output node dum through an RZ path activated by the transistors M9 and M11, and an internal node of a current path (i.e., signal path of B) that will be later activated between the shared current source 918 and the data output node Outn is reset in advance through the transistor M6. Since a current cell of the tail CS-shared sub-DAC 901_1 has a reset function for resetting an internal node of the current cell, the code-dependent non-linearity can be reduced, and the operation speed can be increased.

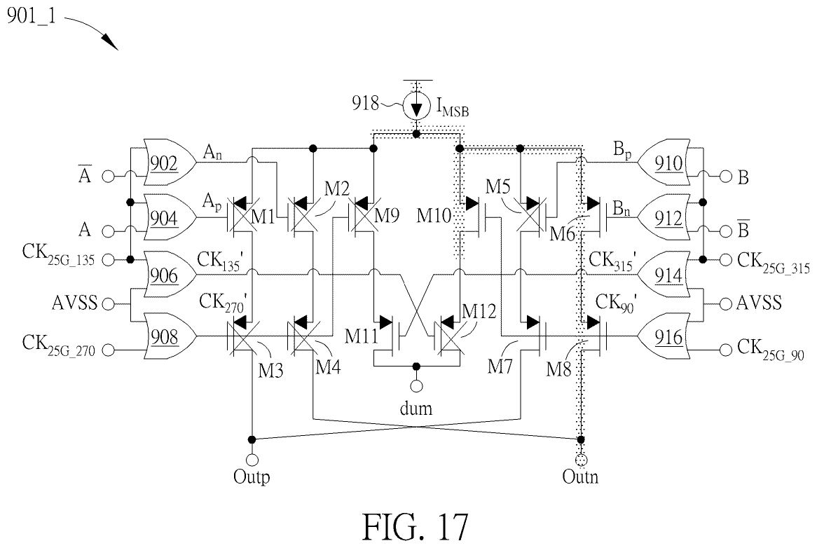

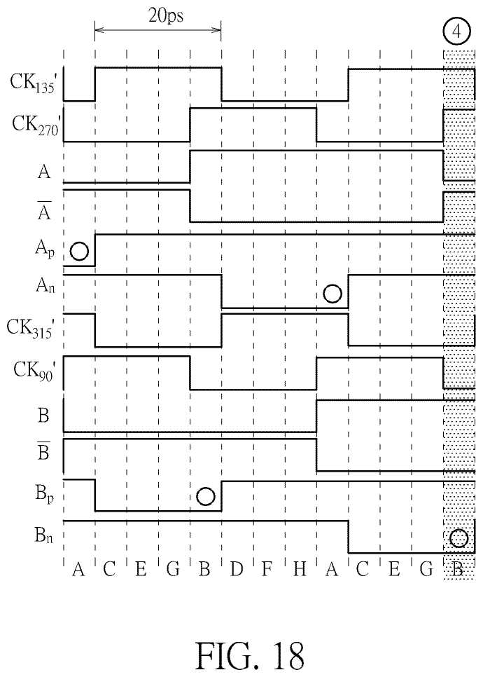

Please refer to FIG. 17 in conjunction with FIG. 18. FIG. 17 is a diagram illustrating a signal phase of B of the tail CS-shared sub-DAC 901_1 according to an embodiment of the present invention. FIG. 18 is a diagram illustrating a period (labeled by a circled number 4) in which the tail CS-shared sub-DAC 901_1 operates in the signal phase of B. The transistors M3, M4 (i.e., clock switches of one signal path circuit) and the transistor M9 are turned off due to CK₂₇₀′=1. The transistors M7, M8 (i.e., clock switches of the other signal path circuit) and the transistor M10 are turned on due to CK₉₀′=0. The transistors M1 and M2 (i.e., data switches of one signal path circuit) are both turned off due to Aₚ=1 and Aₙ=1. One of the transistors M5 and M6 (i.e., data switches of the other signal path circuit) is turned on, depending upon the input data B=(B, B̅) from which the control signals Bₚ and Bₙ are derived. In this example, the transistor M5 is turned off due to Bₚ=1, and the transistor M6 is turned on due to Bₙ=0. The transistor M11 is turned on due to CK₃₁₅′=0. The transistor M12 is turned off due to CK₁₃₅′=1. Hence, the constant current I_{MSB} is provided to the data output node Outn through a current path (i.e., signal path of B) activated by transistors M6 and M8.

As illustrated in FIG. 11 to FIG. 18, a data switch circuit (which includes transistors M1 and M2) and a clock switch circuit (which includes transistors M3 and M4) of one signal path circuit jointly activate/provide a current path for passing current I_{MSB} between the shared current source 918 and the data output port (Outp, Outn) during a first period (e.g., 1 UI), and a data switch circuit (which includes transistors M5 and M6) and a second clock switch circuit (which includes transistors M7 and M8) jointly activate/provide a current path for passing current I_{MSB} between the shared current source 918 and the data output port (Outp, Outn) during a second period (e.g., 1 UI), where none of the control signals CK₂₇₀′ and CK₉₀′ has a pulse width equal to any of the first period (e.g., 1 UI) and the second period (e.g., 1 UI). Specifically, one UI can be interpolated within the current cell of the tail CS-shared sub-DAC 901_1 through control signals Aₚ, Aₙ, CK₁₃₅′, CK₂₇₀′ each having an on-time (logic high duration) and an off-time (logic low duration) both longer than one UI. There is no need for narrow-width pulse generator(s) or logic(s).

Furthermore, symbols (e.g., pulse amplitude modulation (PAM) symbols) are sequentially fed into each sub-DAC of a TI-DAC. As illustrated in FIG. 11 to FIG. 18, the tail CS-shared sub-DAC 901_1 has a constant switching behavior from symbol to symbol, leading to minimum power supply induced jitter (PSIJ).

In this embodiment, the circuit design of the tail CS-shared sub-DAC 901_1 is based on the circuit design of the DAC cell shown in FIG. 1. Since the same current source 918 is shared between two sub-DACs (which can be used for dealing with digital-to-analog conversion of input data A and B), static power and area can be saved. Regarding a first signal path circuit of the tail CS-shared sub-DAC 901_1, the data switch circuit (which includes transistors M1 and M2) is close to the shared current source 918, while the clock switch circuit (which includes transistors M3 and M4) is close to the data output port (Outp, Outn). During the signal phase of A, the data switch circuit (which includes transistors M1 and M2) and the clock switch circuit (which includes transistors M3 and M4) jointly activate/provide a first current path between the shared current source 918 and the data output port (Outp, Outn), where the first current path includes a first transistor included in the data switch circuit (which includes transistors M1 and M2) and a second transistor included in the clock switch circuit (which includes transistors M3 and M4). Since the data switch circuit (which includes transistors M1 and M2) is close to the shared current source 918 and the clock switch circuit (which includes transistors M3 and M4) is close to the data output port (Outp, Outn), the first transistor is turned on and the second transistor is turned off during a period of the RZ phase (Reset phase of A), and the first transistor and the second transistor are both turned on during a period of the signal phase of A following the period of the RZ phase (Reset phase of A). In this way, the code-dependent non-linearity at the internal node can be reset by the data switch circuit (particularly, the first transistor of the data switch circuit), and the switching glitch induced by the data switch circuit (particularly, the first transistor of the data switch circuit) can be gated by the clock switch circuit (particularly, the second transistor of the clock switch circuit), where the switching glitch caused by the clock switch circuit is code-independent.

Similarly, regarding a second signal path circuit of the tail CS-shared sub-DAC 901_1, the data switch circuit (which includes transistors M5 and M6) is close to the shared current source 918, while the clock switch circuit (which includes transistors M7 and M8) is close to the data output port (Outp, Outn). During the signal phase of B, the data switch circuit (which includes transistors M5 and M6) and the clock switch circuit (which includes transistors M7 and M8) jointly activate/provide a second current path between the shared current source 918 and the data output port (Outp, Outn), where the second current path includes a third transistor included in the data switch circuit (which includes transistors M5 and M6) and a fourth transistor included in the clock switch circuit (which includes transistors M7 and M8). Since the data switch circuit (which includes transistors M5 and M6) is close to the shared current source 918 and the clock switch circuit (which includes transistors M7 and M8) is close to the data output port (Outp, Outn), the third transistor is turned on and the fourth transistor is turned off during a period of the RZ phase (Reset phase of B), and the third transistor and the fourth transistor are both turned on during a period of the signal phase of B following the period of the RZ phase (Reset phase of B). In this way, the code-dependent non-linearity at an internal node can be reset by the data switch circuit (particularly, the third transistor of the data switch circuit), and the switching glitch induced by the data switch circuit (particularly, the third transistor of the data switch circuit) can be gated by the clock switch circuit (particularly, the fourth transistor of the clock switch circuit), where the switching glitch caused by the clock switch circuit is code-independent.

In some embodiments of the present invention, a circuit design of each tail CS-shared sub-DAC may be based on the circuit design of the DAC cell shown in FIG. 2. In other words, the tail CS-shared sub-DAC 901_1 may be modified to swap a data switch circuit and a clock switch circuit in the same signal path circuit. Since the same current source 918 is shared between two sub-DACs (which can be used for dealing with digital-to-analog conversion of input data A and B), static power and area can be saved. Regarding a first signal path circuit of the tail CS-shared sub-DAC 901_1 after modification, the clock switch circuit (which includes transistors M3 and M4) is close to the shared current source 918, while the data switch circuit (which includes transistors M1 and M2) is close to the data output port (Outp, Outn). During the signal phase of A, the clock switch circuit (which includes transistors M3 and M4) and the data switch circuit (which includes transistors M1 and M2) jointly activate/provide a first current path between the shared current source 918 and the data output port (Outp, Outn), where the first current path includes a first transistor included in the clock switch circuit (which includes transistors M3 and M4) and a second transistor included in the data switch circuit (which includes transistors M1 and M2). Since the clock switch circuit (which includes transistors M3 and M4) is close to the shared current source 918 and the data switch circuit (which includes transistors M1 and M2) is close to the data output port (Outp, Outn), the first transistor is turned on and the second transistor is turned off during a period of the RZ phase (Reset phase of A), and the first transistor and the second transistor are both turned on during a period of the signal phase of A following the period of the RZ phase (reset phase of A). For example, the clock inputs CK_{25G_135} and CK_{25G_270} may also be swapped. Hence, the clock input CK_{25G_270} of the logic circuit 908 (which is used for generating a control signal of the clock switches M3 and M4) may be modified to receive the clock CK_{25G_135}, and the clock input CK_{25G_135} of the logic circuit 902/904 (which is used for generating a control signal of the data switch M1/M2) may be modified to receive the clock CK_{25G_270}. In this way, the code-dependent non-linearity at an internal node can be reset by the clock switch circuit (particularly, the first transistor of the clock switch circuit). The switching glitch caused by the clock switch circuit is code-independent. However, the switching glitch induced by the data switch circuit (particularly, the first transistor of the data switch circuit) is code-independent. In some embodiments of the present invention, glitch compensation with asymmetry phase control can be used to reduce the code-dependent non-linearity induced by the data switch circuit that is close to the data output port.

Similarly, regarding a second signal path circuit of the tail CS-shared sub-DAC 901_1 after modification, the clock switch circuit (which includes transistors M7 and M8) is close to the shared current source 918, and the data switch circuit (which includes transistors M5 and M6) is close to the data output port (Outp, Outn). During the signal phase of B, the clock switch circuit (which includes transistors M7 and M8) and the data switch circuit (which includes transistors M5 and M6) jointly activate/provide a second current path between the shared current source 918 and the data output port (Outp, Outn), where the second current path includes a third transistor included in the clock switch circuit (which includes transistors M7 and M8) and a second transistor included in the data switch circuit (which includes transistors M5 and M6). Since the clock switch circuit (which includes transistors M7 and M8) is close to the shared current source 918 and the data switch circuit (which includes transistors M5 and M6) is close to the data output port (Outp, Outn), the first transistor is turned on and the second transistor is turned off during a period of the RZ phase (Reset phase of B), and the first transistor and the second transistor are both turned on during a period of the signal phase of B following the period of the RZ phase (reset phase of B). For example, the clock inputs CK_{25G_315} and CK_{25G_90} may also be swapped. Hence, the clock input CK_{25G_90} of the logic circuit 916 (which is used for generating a control signal of the clock switches M7 and M8) may be modified to receive the clock CK_{25G_315}, and the clock input CK_{25G_315} of the logic circuit 910/912 (which is used for generating a control signal of the data switch M5/M6) may be modified to receive the clock CK_{25G_90}. In this way, the code-dependent non-linearity at an internal node can be reset by the clock switch circuit (particularly, the third transistor of the clock switch circuit). The switching glitch caused by the clock switch circuit is code-independent. However, the switching glitch induced by the data switch circuit (particularly, the fourth transistor of the data switch circuit) is code-independent. In some embodiments of the present invention, glitch compensation with asymmetry phase control can be used to reduce the code-dependent non-linearity induced by the data switch circuit that is close to the data output port).

As shown in FIG. 9, the TI-DAC 900 includes 4 tail CS-shared sub-DACs 901_1, 901_2, 901_3, 901_4 to support 8 channels. In some embodiments of the present invention, each tail CS-shared sub-DAC in a TI-DAC may be modified to support re-configurability. In this way, a reconfigurable TI-DAC can be used to meet different digital-to-conversion requirements.

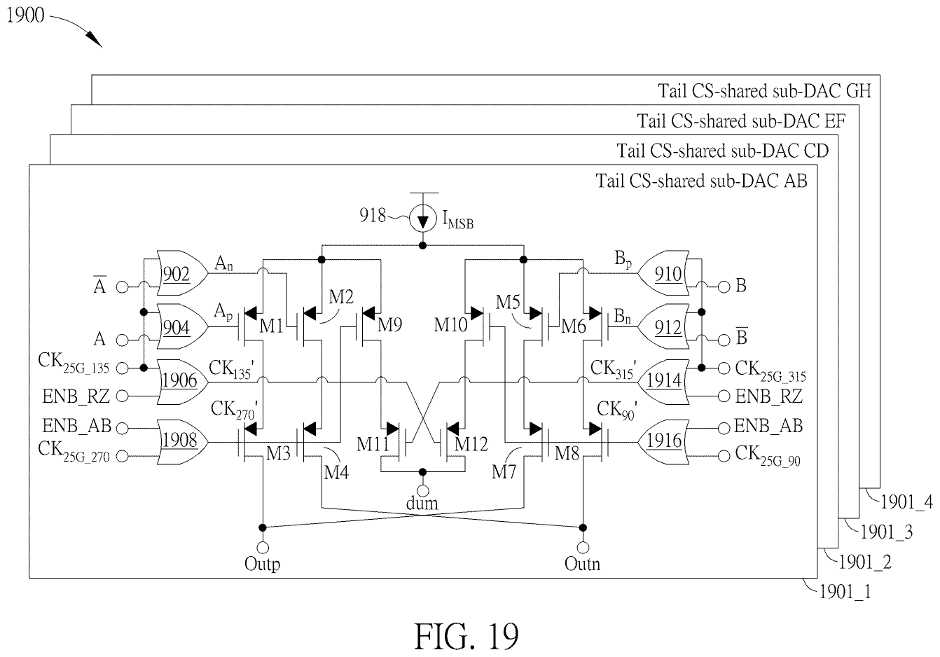

FIG. 19 is a diagram illustrating a fourth TI-DAC using multiple tail CS-shared sub-DACs according to an embodiment of the present invention. The TI-DAC 1900 includes 4 tail CS-shared sub-DACs 1901_1, 1901_2, 1901_3, 1901_4. As shown in FIG. 19, the tail CS-shared sub-DAC (labeled by “Tail CS-shared sub-DAC AB”) 1901_1 includes sub-DACs (which can be used for dealing with digital-to-analog conversion of input data A and B, if enabled) that share the same current source, the tail CS-shared sub-DAC (labeled by “Tail CS-shared sub-DAC CD”) 1901_2 includes sub-DACs (which can be used for dealing with digital-to-analog conversion of input data C and D, if enabled) that share the same current source, the tail CS-shared sub-DAC (labeled by “Tail CS-shared sub-DAC EF”) 1901_3 includes sub-DACs (which can be used for dealing with digital-to-analog conversion of input data E and F, if enabled) that share the same current source, and the tail CS-shared sub-DAC (labeled by “Tail CS-shared sub-DAC GH”) 1901_4 includes sub-DACs (which can used for dealing with digital-to-analog conversion of input data G and H, if enabled) that share the same current source. The tail CS-shared sub-DACs 1901_1, 1901_2, 1901_3, 1901_4 employ the same tail CS-shared sub-DAC architecture. For brevity and simplicity, only the circuit design of the tail CS-shared sub-DAC 1901_1 is illustrated in FIG. 19. Specifically, for better comprehension of technical features of the present invention, only one DAC cell of the tail CS-shared sub-DAC 1901_1 is illustrated. In practice, the tail CS-shared sub-DAC 1901_1 may include multiple DAC cells (e.g., current cells) jointly used for converting one 8b symbol into an analog output and outputting the analog output within one UI (1 UI=5 ps).

The main difference between the tail CS-shared sub-DAC 901_1/901_2/901_3/901_4 shown in FIG. 9 and the tail CS-shared sub-DACs 1901_1/1901_2/1901_3/1901_4 shown in FIG. 19 is that the tail CS-shared sub-DAC 1901_1/1901_2/1901_3/1901_4 supports re-configurability. For example, the tail CS-shared sub-DAC 1901_1 includes a logic circuit 1906 configured to generate the control signal CK₁₃₅′, a logic circuit 1908 configured to generate the control signal CK₂₇₀′, a logic circuit 1914 configured to generate the control signal CK₃₁₅′, and a logic circuit 1916 configured to generate the control signal CK₉₀′. In addition to the clocks CK_{25G_135}, the logic circuit 1906 further receives an enable signal ENB_RZ which is set to control whether the RZ path circuit (which includes transistors M9, M10, M11, M12) is enabled. In addition to the clocks CK_{25G_315}, the logic circuit 1914 further receives the enable signal ENB_RZ which is set to control whether the RZ path circuit (which includes transistors M9, M10, M11, M12) is enabled. In addition to the clocks CK_{25G_270}, the logic circuit 1908 further receives an enable signal ENB_AB which is set to control whether the tail CS-shared sub-DAC 1901_1 is enabled. In addition to the clocks CK_{25G_90}, the logic circuit 1916 further receives the enable signal ENB_AB which is set to control whether the tail CS-shared sub-DAC 1901_1 is enabled. Specifically, the logic circuit 1906 is configured to perform a logic operation (e.g., OR operation) upon the enable signal ENB_RZ and the clock CK_{25G_135} to generate the control signal CK₁₃₅′; the logic circuit 1914 is configured to perform a logic operation (e.g., OR operation) upon the enable signal ENB_RZ and the clock CK_{25G_315} to generate the control signal CK₃₁₅′; the logic circuit 1908 is configured to perform a logic operation (e.g., OR operation) upon the enable signal ENB_AB and the clock CK_{25G_270} to generate the control signal CK₂₇₀′; and the logic circuit 1916 is configured to perform a logic operation (e.g., OR operation) upon the enable signal ENB_AB and the clocks CK_{25G_90} to generate the control signal CK₉₀′.

When the enable signal ENB_AB is set by a logic high level (i.e., ENB_AB=1), the control signal CK₂₇₀′ has a logic high level (i.e., CK₂₇₀′=1) regardless of the clock CK_{25G_270}, and the control signal CK₉₀′ has a logic high level (i.e., CK₉₀′=1) regardless of the clock CK_{25G_90}. In this way, the transistors M3, M4, M7, M8 (i.e., clock switches) are all turned off, thereby disabling the tail CS-shared sub-DAC 901_1. When the enable signal ENB_AB is set by a logic low level (i.e., ENB_AB=0), the control signal CK₂₇₀′ is set by the clock CK_{25G_270}, and the control signal CK₉₀′ is set by the clock CK_{25G_90}. In this way, the transistors M3, M4, M7, M8 (i.e., clock switches) are controlled by normal control signals CK₂₇₀′ and CK₉₀′, thereby enabling the tail CS-shared sub-DAC 1901_1.

When the enable signal ENB_RZ is set by a logic high level (i.e., ENB_RZ=1), the control signal CK₁₃₅′ has a logic high level (i.e., CK₁₃₅′=1) regardless of the clock CK_{25G_135}, and the control signal CK₃₁₅′ has a logic high level (i.e., CK₃₁₅′=1) regardless of the clock CK_{25G_315}. In this way, the transistors M11, M12 are both turned off, thereby disabling the RZ path circuit within the tail CS-shared sub-DAC 1901_1. When the enable signal ENB_RZ is set by a logic low level (i.e., ENB_RZ=0), the control signal CK₁₃₅′ is set by the clock CK_{25G_135}, and the control signal CK₃₁₅′ is set by the clock CK_{25G_315}. In this way, the transistors M12, M11 are controlled by normal control signals CK₁₃₅′ and CK₃₁₅′.

Each of the tail CS-shared sub-DACs 1901_1, 1901_2, 1901_3, 19014 receives the enable signal ENB_RZ which is set to control if the RZ path circuit should be enabled. In addition, the tail CS-shared sub-DACs 1901_1, 1901_2, 1901_3, 1901_4 further receive enable signals ENB_AB, ENB_CD, ENB_EF, ENB_GH, respectively. With proper settings of enable signals ENB_AB, ENB_CD, ENB_EF, ENB_GH, the same TI-DAC 1900 can be re-configured to support different digital-to-analog conversion requirements. The settings of enable signals ENB_AB, ENB_CD, ENB_EF, ENB_GH, ENB_RZ and clocks CK_{25G_0}, CK_{25G_45}, CK_{25G_90}, CK_{25G_135}, CK_{25G_180}, CK_{25G_225}, CK_{25G_270}, CK_{25G_315} for different channel numbers 8X, 4X, 2X are listed in the following table. However, this is for illustrative purposes only, and is not meant to be a limitation of the present invention.

TABLE 2

| Control | 8X | 4X | 2X |
|---|---|---|---|
| ENB_RZ | 0 or 1 | 0 or 1 | 1 |
| ENB_AB | 0 | 0 | 0 |
| ENB_CD | 0 | 1 | 1 |
| ENB_EF | 0 | 0 | 1 |
| ENB_GH | 0 | 1 | 1 |
| CK_{25G}_{_{—}}₀ | 0° | 0° | 0° |
| CK_{25G}_{_{—}}₄₅ | 45° | 90° | 0° |
| CK_{25G}_{_{—}}₉₀ | 90° | 90° | 0° |
| CK_{25G}_{_{—}}₁₃₅ | 135° | 180° | 180° |
| CK_{25G}_{_{—}}₁₈₀ | 180° | 180° | 180° |
| CK_{25G}_{_{—}}₂₂₅ | 225° | 270° | 180° |
| CK_{25G}_{_{—}}₂₇₀ | 270° | 270° | 180° |
| CK_{25G}_{_{—}}₃₁₅ | 315° | 0° | 0° |

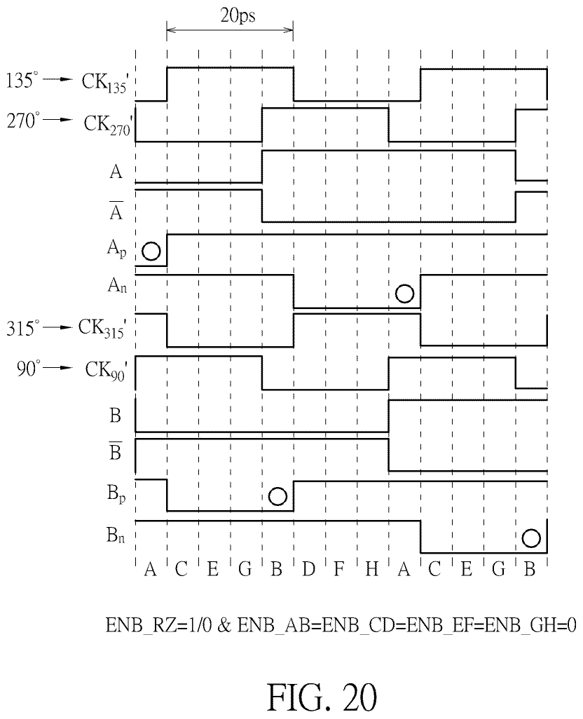

If all of the 8b 25 GSps tail CS-shared sub-DACs 1901_1, 1901_2, 1901_3, 1901_4 are enabled by ENB_AB=ENB_CD=ENB_EF=ENB_GH=0, the TI-DAC 1900 is configured to act as an 8b 200 GSps eight-channel TI-DAC, and 8-phase clocks (0°, 45°, 90°, 135°, 180°, 225°, 270°, 315°) are used for generating control signals needed by the enabled tail CS-shared sub-DACs 1901_1, 1901_2, 1901_3, 1901_4. FIG. 20 is a diagram illustrating settings of clocks used by the tail CS-shared sub-DAC 1901_1 that is enabled under ENB_AB=ENB_CD=ENB_EF=ENB_GH=0 according to an embodiment of the present invention.

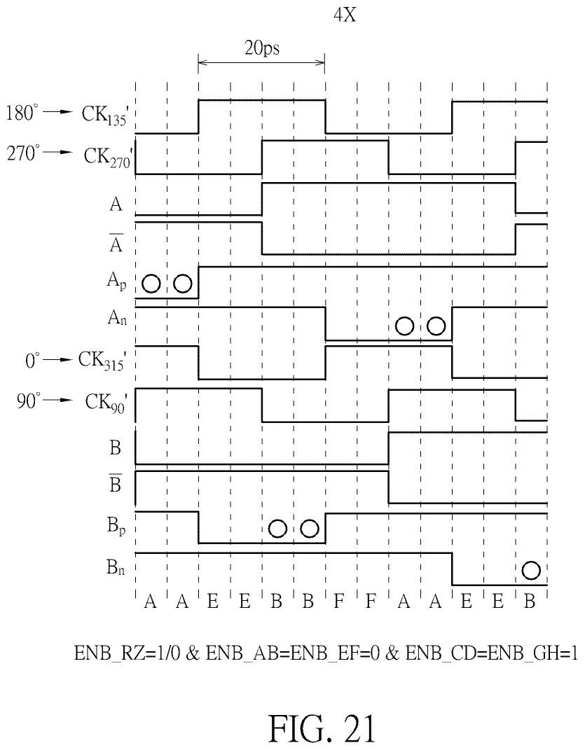

If only two of the 8b 25 GSps tail CS-shared sub-DACs 1901_1, 1901_2, 1901_3, 1901_4 are enabled by ENB_AB=ENB_EF=0 & ENB_CD=ENB_GH=1, the TI-DAC 1900 is configured to act as an 8b 100 GSps four-channel TI-DAC, and 4-phase clocks (0°, 90°, 180°, 270°) are used for generating control signals needed by the enabled tail CS-shared sub-DACs 1901_1 and 1901_3. FIG. 21 is a diagram illustrating settings of clocks used by the tail CS-shared sub-DAC 1901_1 that is enabled under ENB_AB=ENB_EF=0 & ENB_CD=ENB_GH=1 according to an embodiment of the present invention. Specifically, the clock input CK_{25G_135} specified in the circuit design of the tail CS-shared sub-DACs 1901_1 is re-configured to receive the clock CK_{25G_180}, and the clock input CK_{25G_315} specified in the circuit design of the tail CS-shared sub-DACs 1901_1 is re-configured to receive the clock CK_{25G_0}.

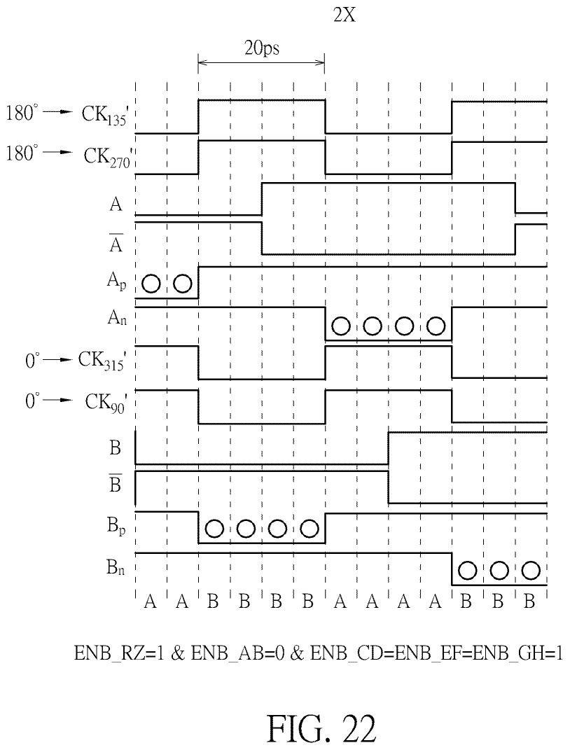

If only one of the 8b 25 GSps tail CS-shared sub-DACs 1901_1, 1901_2, 1901_3, 1901_4 is enabled by ENB_AB=0 & ENB_CD=ENB_EF=ENB_GH=1, the TI-DAC 1900 is configured to act as an 8b 50 GSps two-channel TI-DAC, and 2-phase clocks (0°, 180°) are used for generating control signals needed by the enabled tail CS-shared sub-DAC 1901_1. FIG. 22 is a diagram illustrating settings of clocks used by the tail CS-shared sub-DAC 1901_1 that is enabled under ENB_AB=0 & ENB_CD=ENB_EF=ENB_GH=1 according to an embodiment of the present invention. Specifically, the clock input CK_{25G_135} specified in the circuit design of the tail CS-shared sub-DACs 1901_1 is re-configured to receive the clock CK_{25G_180}, the clock input CK_{25G_270} specified in the circuit design of the tail CS-shared sub-DACs 1901_1 is re-configured to receive the clock CK_{25G_180}, the clock input CK_{25G_315} specified in the circuit design of the tail CS-shared sub-DACs 1901_1 is re-configured to receive the clock CK_{25G_0}, and the clock input CK_{25G_90} specified in the circuit design of the tail CS-shared sub-DACs 1901_1 is re-configured to receive the clock CK_{25G_0}.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A digital-to-analog converter (DAC) circuit comprising:
a first sub-DAC, comprising:
a shared current source;
a first signal path circuit, comprising:
a first data switch circuit, controlled by a first set of control signals, wherein the first set of control signals depends on a first input data; and
a first clock switch circuit, controlled by a first control signal, wherein the first control signal is independent of the first input data, and the first data switch circuit and the first clock switch circuit are series-connected between the shared current source and a data output port;
a second signal path circuit, comprising:
a second data switch circuit, controlled by a second set of control signals, wherein the second set of control signals depends on a second input data; and
a second clock switch circuit, controlled by a second control signal, wherein the second control signal is independent of the second input data, and the second data switch circuit and the second clock switch circuit are series-connected between the shared current source and the data output port; and
a return-to-zero (RZ) path circuit, controlled by at least one RZ control signal, wherein the at least one RZ control signal is independent of the first input data and the second input data, and the RZ path circuit is coupled between the shared current source and a dummy output node.

2. The DAC circuit of claim 1, wherein the first sub-DAC and the second sub-DAC are sequentially active to drive the data output port, and the first signal path circuit and the second signal path circuit of the first sub-DAC are sequentially active to drive the data output port.

3. The DAC circuit of claim 2, wherein the first set of control signals comprises a first data-dependent signal and a second data-dependent signal each derived from the first input data, where the second data-dependent signal is complementary to the first data-dependent signal; the first data switch circuit comprises:
a first transistor, having a control terminal, a first connection terminal, and a second connection terminal, wherein the control terminal of the first transistor is configured to receive the first data-dependent signal; and
a second transistor, having a control terminal, a first connection terminal, and a second connection terminal, wherein the control terminal of the second transistor is configured to receive the second data-dependent signal; and
the first clock switch circuit comprises:
a third transistor, having a control terminal, a first connection terminal, and a second connection terminal, wherein the control terminal of the third transistor is configured to receive the first control signal, and one of the first connection terminal and the second connection terminal of the third transistor is coupled to one of the first connection terminal and the second connection terminal of the first transistor; and
a fourth transistor, having a control terminal, a first connection terminal, and a second connection terminal, wherein the control terminal of the fourth transistor is configured to receive the first control signal, and one of the first connection terminal and the second connection terminal of the fourth transistor is coupled to one of the first connection terminal and the second connection terminal of the second transistor.

4. The DAC circuit of claim 3, wherein the first sub-DAC further comprises:
a glitch cancellation circuit, configured to apply glitch cancellation to the second connection terminal of the first transistor and the second connection terminal of the second transistor.

5. The DAC circuit of claim 4, wherein the glitch cancellation circuit comprises:
a fifth transistor, having a control terminal, a first connection terminal, and a second connection terminal, wherein the control terminal of the fifth transistor is configured to receive the first data-dependent signal, the first connection terminal of the fifth transistor is coupled to a reference voltage, and the second connection terminal of the fifth transistor is coupled to the second connection terminal of the second transistor; and
a sixth transistor, having a control terminal, a first connection terminal, and a second connection terminal, wherein the control terminal of the sixth transistor is configured to receive the second data-dependent signal, the first connection terminal of the sixth transistor is coupled to the reference voltage, and the second connection terminal of the sixth transistor is coupled to the second connection terminal of the first transistor.

6. The DAC circuit of claim 2, wherein the first input data comprises a first data signal and a second data signal, where the second data signal is complementary to the first data signal; and the first sub-DAC further comprises:
a first logic circuit, configured to perform a first logic operation upon the first data signal to generate the first data-dependent signal;
a second logic circuit, configured to perform a second logic operation upon the second data signal to generate the second data-dependent signal;
a third logic circuit, configured to perform a third logic operation upon first clocks to generate the first control signal; and
a fourth logic circuit, configured to perform a fourth logic operation upon second clocks to generate the second control signal;
wherein the first clocks and the second clocks include clocks having a same frequency but different phases.

7. The DAC circuit of claim 6, wherein each of the third logic circuit and the fourth logic circuit is further configured to receive an enable signal which is set to control whether the first sub-DAC is enabled.

8. The DAC circuit of claim 2, wherein the first sub-DAC further comprises:
a logic circuit, configured to perform a logic operation upon the first control signal and the second control signal to generate the at least one RZ control signal; and
the RZ path circuit comprises:
a first transistor, having a control terminal, a first connection terminal, and a second connection terminal, wherein the control terminal is configured to receive the at least one RZ control signal.

9. The DAC circuit of claim 8, wherein the RZ path circuit further comprises:
a second transistor, having a control terminal, a first connection terminal, and a second connection terminal, wherein the control terminal of the second transistor is configured to receive a reference voltage, and one of the first connection terminal and the second connection terminal of the second transistor is coupled to one of the first connection terminal and the second connection terminal of the first transistor.

10. The DAC circuit of claim 1, further comprising:
a second sub-DAC;
wherein the first sub-DAC and the second sub-DAC are sequentially active to drive the data output port, and the first signal path circuit and the second signal path circuit of the first sub-DAC are non-sequentially active to drive the data output port.

11. The DAC circuit of claim 10, wherein the first set of control signals comprises a first data-dependent signal and a second data-dependent signal each derived from the first input data; the first data switch circuit comprises:
a first transistor, having a control terminal, a first connection terminal, and a second connection terminal, wherein the control terminal of the first transistor is configured to receive the first data-dependent signal; and
a second transistor, having a control terminal, a first connection terminal, and a second connection terminal, wherein the control terminal of the second transistor is configured to receive the second data-dependent signal; and
the first clock switch circuit comprises:
a third transistor, having a control terminal, a first connection terminal, and a second connection terminal, wherein the control terminal of the third transistor is configured to receive the first control signal, and one of the first connection terminal and the second connection terminal of the third transistor is coupled to one of the first connection terminal and the second connection terminal of the first transistor; and
a fourth transistor, having a control terminal, a first connection terminal, and a second connection terminal, wherein the control terminal of the fourth transistor is configured to receive the first control signal, and one of the first connection terminal and the second connection terminal of the fourth transistor is coupled to one of the first connection terminal and the second connection terminal of the second transistor.

12. The DAC circuit of claim 11, wherein each of the first transistor, the second transistor, the third transistor, and the fourth transistor is configured to operate in a linear region.

13. The DAC circuit of claim 11, wherein the at least one RZ control signal comprises the first control signal, the second control signal, a third control signal, and a fourth control signal; and the RZ path circuit comprises:
a fifth transistor, having a control terminal, a first connection terminal, a second connection terminal, wherein the control terminal of the fifth transistor is configured to receive the first control signal;
a sixth transistor, having a control terminal, a first connection terminal, a second connection terminal, wherein the control terminal of the sixth transistor is configured to receive the second control signal;
a seventh transistor, having a control terminal, a first connection terminal, a second connection terminal, wherein the control terminal of the seventh transistor is configured to receive the fourth control signal, and one of the first connection terminal and the second connection terminal of the seventh transistor is coupled to one of the first connection terminal and the second connection terminal of the fifth transistor; and
an eighth transistor, having a control terminal, a first connection terminal, a second connection terminal, wherein the control terminal of the eighth transistor is configured to receive the third control signal, and one of the first connection terminal and the second connection terminal of the eighth transistor is coupled to one of the first connection terminal and the second connection terminal of the sixth transistor.

14. The DAC circuit of claim 13, wherein the first sub-DAC further comprises:
a first logic circuit, configured to perform a first logic operation upon at least a first clock to generate the third control signal;
a second logic circuit, configured to perform a second logic operation upon at least a second clock to generate the first control signal;
a third logic circuit, configured to perform a third logic operation upon at least a third clock to generate the fourth control signal; and
a fourth logic circuit, configured to perform a fourth logic operation upon at least a fourth clock to generate the second control signal;
wherein the first clock, the second clock, the third clock, and the fourth clock include clocks having a same frequency but different phases.

15. The DAC circuit of claim 14, wherein each of the second logic circuit and the fourth logic circuit is further configured to receive a first enable signal which is set to control whether the first sub-DAC is enabled; and each of the first logic circuit and the third logic circuit is further configured to receive a second enable signal which is set to control whether the RZ path circuit is enabled.

16. The DAC circuit of claim 11, wherein the first input data comprises a first data signal and a second data signal, where the second data signal is complementary to the first data signal; the first sub-DAC further comprises:
a first logic circuit, configured to perform a first logic operation upon the first data signal and a first clock to generate the first data-dependent signal;
a second logic circuit, configured to perform a second logic operation upon the second data signal and the first clock to generate the second data-dependent signal; and
a third logic circuit, configured to perform a third logic operation upon at least a second clock to generate the first control signal.

17. The DAC circuit of claim 16, wherein the third logic circuit is further configured to receive an enable signal which is set to control whether the first sub-DAC is enabled.

18. The DAC circuit of claim 11, wherein the first data switch circuit is coupled between the shared current source and the first clock switch circuit, and the first clock switch circuit is coupled between the first data switch circuit and the data output port.

19. The DAC circuit of claim 18, wherein the first data switch circuit and the first clock switch circuit jointly activate a current path between the shared current source and the data output port, where the current path includes one transistor of the first data switch circuit and one transistor of the first clock switch circuit, said one transistor of the first data switch circuit is turned on and said one transistor of the first clock switch circuit is turned off during a first period, and said one transistor of the first data switch circuit and said one transistor of the first clock switch circuit are both turned on during a second period following the first period.

20. The DAC circuit of claim 11, wherein the first clock switch circuit is coupled between the shared current source and the first data switch circuit, and the first data switch circuit is coupled between the first clock switch circuit and the data output port.

21. The DAC circuit of claim 20, wherein the first clock switch circuit and the first data switch circuit jointly activate a current path between the shared current source and the data output port, where the current path includes one transistor of the first clock switch circuit and one transistor of the first data switch circuit, said one transistor of the first clock switch circuit is turned on and said one transistor of the first data switch circuit is turned off during a first period, and said one transistor of the first clock switch circuit and said one transistor of the first data switch circuit are both turned on during a second period following the first period.

22. The DAC circuit of claim 10, wherein the first data switch circuit and the first clock switch circuit jointly activate a first current path for passing current between the shared current source and the data output port during a first period, the second data switch circuit and the second clock switch circuit jointly activate a second current path for passing current between the shared current source and the data output port during a second period, and none of the first control signal and the second control signal has a pulse width equal to any of the first period and the second period.

23. The DAC circuit of claim 10, wherein the first sub-DAC has a constant switching behavior from symbol to symbol.
